(19) United States
(12) Patent Application Publication
(10) Pub. No.: US 2016/0006452 A1
(43) Pub. Date: Jan. 7, 2016

(54) ANALOG-TO-DIGITAL CONVERTER, METHOD FOR DRIVING THE SAME, IMAGE SENSOR, IMAGING APPARATUS, AND BATTERY MONITORING SYSTEM

(71) Applicant: PANASONIC INTELLECTUAL PROPERTY MANAGEMENT CO., LTD., Osaka (JP)

(72) Inventor: Ayuhiko SAITO, Osaka (JP)

(21) Appl. No.: 14/857,751

(22) Filed: Sep. 17, 2015

Related U.S. Application Data
(63) Continuation of application No. PCT/JP2014/005361, filed on Oct. 22, 2014.

(30) Foreign Application Priority Data
Dec. 12, 2013 (JP) 2013-256769

(51) Int. Cl. H03M 3/00; G01R 31/36; H04N 5/378

(52) U.S. Cl. CPC H03M 3/418; H03M 3/464; H04N 5/378; G01R 31/3651

(57) ABSTRACT

Provided is an A/D converter including: a first integrator integrating a signal obtained by adding a first feedback signal and a third feedback signal to an analog input signal, to generate a first output signal; a first quantizer converting the first output signal into a first digital signal; a first D/A converter converting the first digital signal into a first analog signal; a second integrator integrating a signal obtained by adding the first analog signal and a second feedback signal to the first output signal, to generate a second output signal; a second quantizer converting the second output signal into a second digital signal; and a second D/A converter converting the second digital signal into a second analog signal, wherein the first feedback signal is the first analog signal, the second feedback signal is the second analog signal, and the third feedback signal is the second analog signal.

### CROSS REFERENCE TO RELATED APPLICATION

This is a continuation application of PCT International Application No. PCT/JP2014/005361 filed on Oct. 22, 2014, designating the United States of America, which is based on and claims priority of Japanese Patent Application No. 2013-256769 filed on Dec. 12, 2013. The entire disclosures of the above-identified applications, including the specifications, drawings and claims are incorporated herein by reference in their entirety.

### FIELD

The present disclosure relates to an analog-to-digital (hereinafter abbreviated as “A/D”) converter, a method for driving the A/D converter, an image sensor including the A/D converter, an imaging apparatus including the image sensor, and a battery monitoring system including the A/D converter.

### BACKGROUND

Patent Literature (hereinafter abbreviated as “PTL”) 1 discloses an oversampling A/D converter that highly accurately converts an analog input signal input from outside of the A/D converter into a digital signal, at an extremely higher frequency than that of the analog input signal.

PTL 1 also discloses an A/D converter including delta-sigma modulators at N stages that are cascaded, where N is an integer of two or more. Each of the N delta-sigma modulators includes an adder, an integrator, a quantizer, and a digital-to-analog (hereinafter abbreviated as “D/A”) converter that performs D/A conversion, all of which are connected in series in this order to form a loop. Similarly, the delta-sigma modulator at the second stage includes a second adder that adds an analog input signal and the output signal from a D/A converter, an integrator that integrates the output signal from the second adder, a quantizer that quantizes the output signal from the integrator, and the D/A converter, all of which are connected in series in this order to form a loop. The delta-sigma modulator at the first stage receives an analog input signal, and the delta-sigma modulators at the second and subsequent stages receive output signals from delta-sigma modulators that precede the delta-sigma modulators at the second and subsequent ones of the stages. Here, the A/D converter outputs a signal obtained by adding (i) all the output signals from differentiators of the delta-sigma modulators at the second to the N stages and (ii) the loop output signal from the first quantization loop as a digital output signal. Accordingly, the A/D converter with high linearity can be achieved.

### CITATION LIST

### Patent Literature

[PTL 1] Japanese Patent No. 1639746

### SUMMARY

### Technical Problem

However, the A/D converter disclosed in PTL 1 has a mismatch between the delta-sigma modulators and the digital filter due to decrease in accuracy of the integrators. Thus, a problem of decrease in accuracy of the A/D converter occurs.

Thus, an object of the present disclosure is to provide an A/D converter that has high linearity and can suppress decrease in accuracy due to the mismatch, and a method for driving the A/D converter. Furthermore, another object is to provide an image sensor, an imaging apparatus, and a battery monitoring system each including the A/D converter.

### Solution to Problem

The A/D converter according to the present disclosure is an A/D converter including: a first integrator that integrates a signal obtained by adding a first feedback signal and a third feedback signal to an analog input signal, to generate a first output signal; a first quantizer that converts the first output signal into a first digital signal; a first D/A converter that converts the first digital signal into a first analog signal; a second integrator that integrates a signal obtained by adding the first analog signal and a second feedback signal to the first output signal, to generate a second output signal; a second quantizer that converts the second output signal into a second digital signal; and a second D/A converter that converts the second digital signal into a second analog signal, wherein the first feedback signal is the first analog signal, the second feedback signal is the second analog signal, and the third feedback signal is the second analog signal.

### Advantageous Effects

The A/D converter according to the present disclosure has high linearity, and is effective at obtaining A/D conversion characteristics that suppress decrease in accuracy by a mismatch between delta-sigma modulators and a digital filter in the A/D converter.

### BRIEF DESCRIPTION OF DRAWINGS

These and other objects, advantages and features of the invention will become apparent from the following description thereof taken in conjunction with the accompanying drawings that illustrate a specific embodiment of the present invention.

FIG. 1 is a block diagram of an A/D converter according to Embodiment 1;

FIG. 2 is a circuit diagram that exemplifies the A/D converter according to Embodiment 1;

FIG. 3A is a circuit diagram of another configuration of a D/A converter according to Embodiment 1;

FIG. 3B is a circuit diagram of another configuration of an D/A converter according to Embodiment 1;

FIG. 3C is a circuit diagram of another configuration of an D/A converter according to Embodiment 1;

FIG. 4A is a timing chart of control signals of switches of the A/D converter according to Embodiment 1;

FIG. 4B is a timing chart of control signals of switches of the A/D converter according to Embodiment 1;

FIG. 5 is a circuit diagram schematically illustrating a configuration of a bipolar second D/A converter according to Embodiment 1;

FIG. 6 is a circuit diagram schematically illustrating an example configuration of a second D/A converter functioning as both bipolar and unipolar D/A converters according to Embodiment 1;

FIG. 7 is a circuit diagram exemplifying an integrator and a quantizer with a reset switch according to Embodiment 1;

FIG. 8 is a timing chart of control signals of switches of an incremental A/D converter according to Embodiment 1;

FIG. 9 graphs a relationship between the number of bits and the maximum linear approximation error when the incremental A/D converter according to Embodiment 1 is used;

FIG. 10 graphs a relationship between the number of bits and the maximum linear approximation error when a conventional incremental A/D converter is used;

FIG. 11 is a functional block diagram of an A/D converter according to Embodiment 2;

FIG. 12 is a block diagram exemplifying a configuration of an image sensor according to Embodiment 3;

FIG. 13 illustrates a digital still camera according to Embodiment 3;

FIG. 14 is a block diagram exemplifying a configuration of a digital still camera according to Embodiment 3;

FIG. 15 is a block diagram exemplifying a configuration of a battery monitoring system according to Embodiment 4; and

FIG. 16 is a block diagram of a multistage A/D converter (A/D converter with three or more stages) according to another Embodiment.

### DESCRIPTION OF EMBODIMENTS

### Embodiment 1

Non-limiting embodiments will be described in detail with reference to the drawings as appropriate. The unnecessary details may be omitted. For example, description of known details and overlapping description of the substantially identical configuration may be omitted. This prevents the following description to be unnecessarily redundant, and facilitates better understanding of a person skilled in the art.

The inventors provide the drawings and the description so that the person skilled in the art fully understands the present disclosure, but do not intend to limit the scope of the claims.

### Embodiment 1

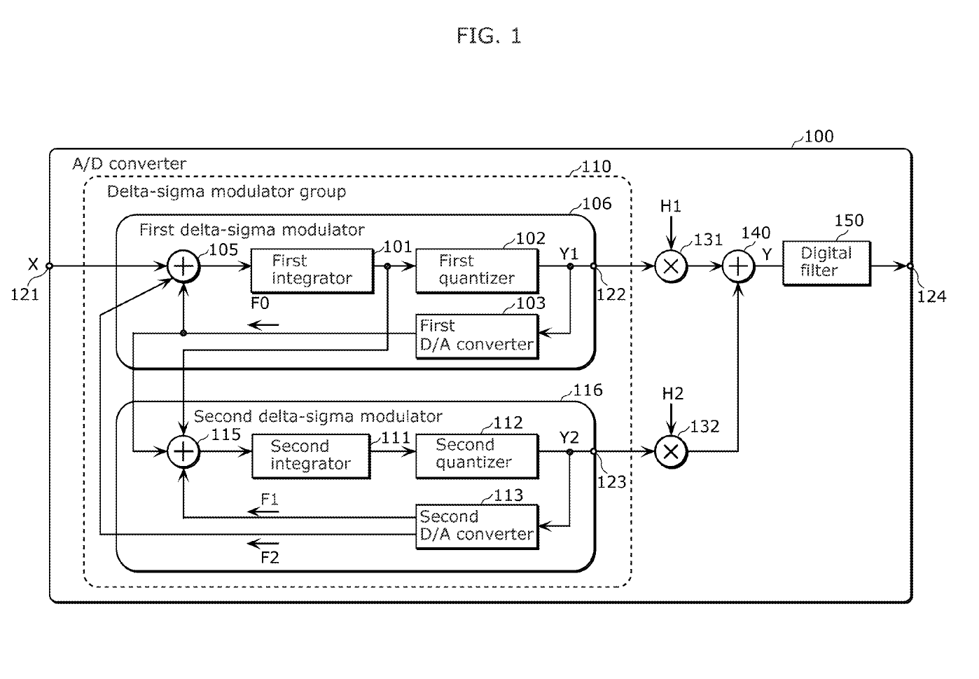

Embodiment 1 will be described with reference to FIGS. 1 to 10.

An A/D converter according to Embodiment 1 includes delta-sigma modulators, and a feedback circuit from the last delta-sigma modulator to the first delta-sigma modulator to reduce an error caused by a mismatch between the delta-sigma modulators and a digital filter.

### [1-1. Overall Configuration]

FIG. 1 is a block diagram of an A/D converter 100 according to Embodiment 1.

As illustrated in FIG. 1, the A/D converter 100 includes an input terminal 121, a delta-sigma modulator group 110 including a first delta-sigma modulator 106 and a second delta-sigma modulator 116, multipliers 131 and 132, an adder 140, a digital filter 150, and an external output terminal 124.

The input terminal 121 is a terminal that receives an analog input signal from outside of the A/D converter 100, whereas the external output terminal 124 is a terminal that outputs a digital signal converted from the analog input signal.

The delta-sigma modulator group 110 includes the first delta-sigma modulator 106 at the first stage and the second delta-sigma modulator 116 at the second stage according to Embodiment 1.

The configuration of the first delta-sigma modulator 106 will be hereinafter described. As illustrated in FIG. 1, the first delta-sigma modulator 106 includes a first integrator 101, a first quantizer 102, a first D/A converter 103, an adder 105, and a first output terminal 122.

The first integrator 101 is a circuit that evaluates a first integral by integrating, with an analog input signal to be input to the input terminal 121, a signal obtained by adding a first feedback signal F0 and a third feedback signal F2, that is, an output signal from the adder 105 to derive an analog signal.

The first quantizer 102 is a circuit that performs a first quantization by quantizing the analog signal output from the first integrator 101 into a digital signal, and outputs the digital signal to the first output terminal 122.

The first D/A converter 103 is a circuit that performs a first D/A conversion by converting the digital signal input from the first quantizer 102 into the first feedback signal F0 that is an analog signal. This first feedback signal F0 is fed back to an input terminal of the first integrator 101 as described above.

The adder 105 adds the analog input signal to be input to the input terminal 121, the first feedback signal F0, and the third feedback signal F2 to generate an addition signal, and outputs the addition signal to the first integrator 101.

The first D/A converter 103 and the adder 105 constitute a feedback circuit in the first delta-sigma modulator 106.

The configuration of the second delta-sigma modulator 116 will be described. The second delta-sigma modulator 116 is a circuit that receives an error of the first delta-sigma modulator 106. Provision of the second delta-sigma modulator 116 and addition of the output signal from the second delta-sigma modulator 116 to the output signal of the first delta-sigma modulator 106 can increase the accuracy of the A/D conversion.

As illustrated in FIG. 1, the second delta-sigma modulator 116 includes a second integrator 111, a second quantizer 112, a second D/A converter 113, an adder 115, and a second output terminal 123.

The second integrator 111 is a circuit that evaluates a second integral by integrating a signal obtained by adding the output signal from the first integrator 101, the output signal from the first D/A converter 103, and a second feedback signal F1, that is, an output signal from the adder 115 to generate an analog signal.

The second quantizer 112 is a circuit that performs a second quantization by quantizing the analog signal output from the second integrator 111 into a digital signal, and outputs the digital signal to the second output terminal 123.

The second D/A converter 113 is a circuit that performs a second D/A conversion by converting the digital signal input from the second quantizer 112 into the second feedback signal F1 and the third feedback signal F2 that are analog signals. The second feedback signal F1 is fed back to an input terminal of the second integrator 111. Furthermore, the third feedback signal F2 is fed back to an input terminal of the first integrator 101. The second feedback signal F1 and the third feedback signal F2 may be the same signal.

The adder 115 adds the output signal from the first integrator 101, the output signal from the first D/A converter 103, and the second feedback signal F1 to generate an addition signal, and outputs the addition signal to the second integrator 111.

The second D/A converter 113 and the adder 115 constitute a feedback circuit in the second delta-sigma modulator 116.

The multiplier 131 is a circuit that multiplies an output signal Y1 from the first delta-sigma modulator 106 with a coefficient H1. The multiplier 132 is a circuit that multiplies an output signal Y2 from the second delta-sigma modulator 116 with a coefficient H2. The adder 140 is a circuit that adds a digital signal output from the multiplier 131 and a digital signal output from the multiplier 132. A method for deriving the coefficients H1 and H2 will be described later. In summary, the coefficients H1 and H2 are derived to cancel the quantization error in the first delta-sigma modulator 106.

The digital filter 150 includes a low-pass filter and a decimation filter that are example band-pass filters according to Embodiment 1. The low-pass filter outputs a signal obtained by removing or reducing signal component exceeding a predetermined frequency, out of the signals input from the adder 140. The decimation filter is a filter that reduces the sampling frequency. The digital filter 150 may include other filters than the low-pass filter and the decimation filter.

### [1-2. Method for Deriving Coefficients H1 and H2]

Operations of the A/D converter 100 with such a configuration will be hereinafter described.

### [1-2-1. When First Integrator is a Single Integrator]

First, the first integrator 101 and the second integrator 111 functioning as single integrators will be described. Assuming that X′ denotes an input signal to a single integrator and Y′ denotes an output signal from the single integrator, a transfer function of the single integrator using a z-function will be expressed as the following Expression 1.

### [Math 1]

$${Y}^{′} = \frac{{Z}^{- 1}}{1 - {Z}^{- 1}} \times {X}^{′} \qquad ( Expression 1 )$$

### (Here,

$${Z}^{- 1} = exp ( - \frac{j ω}{fs} ) ,$$

where ω=2πf and fs indicates a sampling frequency.)

The transfer functions of the first output signal Y1 and the second output signal Y2 are expressed as the following Expression 2a and Expression 2b, respectively, where X denotes a signal to be input to the input terminal 121, E1 denotes quantization noise (quantization error) introduced by the first quantizer 102, E2 denotes quantization noise introduced by the second quantizer 112, Y1 denotes a first output signal from the first quantizer 102, and Y2 denotes a second output signal from the second quantizer 112.

### [Math 2]

Y1=Z⁻¹×(X−Y2)+(1−Z⁻¹)×E1 (Expression 2a)

Y2=−Z⁻¹×E1(1−Z⁻¹)×E2 (Expression 2b)

The first output signal Y1 and the second output signal Y2 are input to the digital filter. The digital filter multiplies the first output signal Y1 and the second output signal Y2 by the coefficient H1 and the coefficient H2, respectively, and adds the resultant signals to generate a digital signal Y.

### [Math 3]

Y=H1×Y1+H2×Y2 (Expression 3)

Here, the coefficients H1 and H2 in Expression 3 are determined to offset the term of E1 included in each of Expressions 2a and 2b. The following Expressions 4a and 4b are examples that satisfy this condition.

### [Math 4]

H1=Z⁻¹ (Expression 4a)

H2=1−Z⁻¹+Z⁻² (Expression 4b)

Substituting Expressions 2a, 2b, 4a, and 4b into Expression 3 yields the following Expression 5.

### [Math 5]

Y=Z⁻²×X+(1−Z⁻¹)²×E2 (Expression 5)

In Expression 5, the term of the quantization noise E1 introduced by the first delta-sigma modulator 106 is offset. Furthermore, the second term on the right hand side is a product of the quantization noise E2 and (1−Z⁻¹)². This indicates that the quantization noise E2 introduced by the second delta-sigma modulator 116 is changed into a high frequency component as a result of the secondary noise shaping. Accordingly, the quantization noise E2 is easily removed by the low-pass filter at the latter stage. Thus, the error caused by the quantization noise E2 introduced by output of the A/D converter 100 can be further reduced.

### [1-2-2. When First Integrator is a Multiple Integrator]

Furthermore, the first integrator 101 may be a multiple integrator in the A/D converter 100 according to Embodiment 1. An example when the first integrator 101 is a double integrator will be described. Here, the second integrator 111 is a single integrator. Assuming that X′ denotes an input signal to the integrator and Y′ denotes an output signal from the integrator, a transfer function of the double integrator using a z-function will be expressed as the following Expression 6.

### [Math 6]

$${Y}^{′} = {( \frac{{Z}^{- 1}}{1 - {Z}^{- 1}} )}^{2} \times {X}^{′} \qquad ( Expression 6 )$$

According to Expression 6, transfer functions of the output signals Y1 and Y2 are expressed as the following Expressions 7a and 7b, respectively.

### [Math 7]

Y1=Z⁻²×(X−Y2)+(1−Z⁻¹)²×E1 (Expression 7a)

Y2=−Z⁻¹×E1+(1−Z⁻¹)×E2 (Expression 7b)

Here, the coefficients H1 and H2 in Expressions 7a and 7b are determined to offset the term of E1 included in each of Expressions 7a and 7b as in the case where the first integrator 101 is a single integrator. The following Expressions 8a and 8b are examples that satisfy this condition.

### [Math 8]

H1=Z⁻¹ (Expression 8a)

H2=1−2Z⁻¹+Z⁻²+Z⁻³ (Expression 8b)

Substituting Expressions 7a, 7b, 8a, and 8b into Expression 3 yields the following Expression 9.

### [Math 9]

Y=Z⁻³×X+(1−Z⁻⁴)³×E2 (Expression 9)

In Expression 9, the term of the quantization noise E1 introduced by the first delta-sigma modulator 106 is offset. Furthermore, the second term on the right hand side is a product of the quantization noise E2 and (1−Z⁻¹)³. This indicates that the quantization noise E2 introduced by the second delta-sigma modulator 116 is changed into a high frequency component as a result of the third-order noise shaping. Accordingly, the quantization noise E2 is easily removed by the low-pass filter at the latter stage. Thus, the error caused by the quantization noise E2 introduced by output of the A/D converter 100 can be further reduced.

Accordingly, the integrator may be any integrator such as a single integrator or a double integrator or higher. The coefficient used by the digital filter is determined to offset the term of E1. As described above, although the single integrator satisfactorily produces the noise shaping effect, a higher-order integrator can increase the noise shaping effect.

### [1-3. Circuit Configuration]

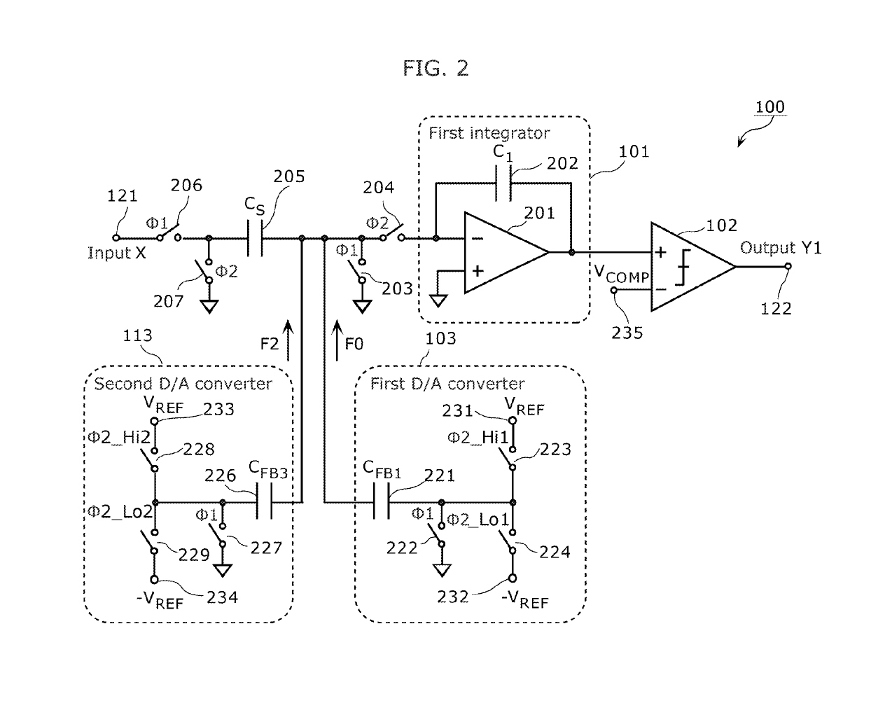

The detailed circuit configuration of the A/D converter 100 will be described with reference to FIG. 2, prior to description of the operations thereof.

FIG. 2 is a circuit diagram that exemplifies the A/D converter 100 in FIG. 1. FIG. 2 illustrates part of the constituent elements of the A/D converter 100 in FIG. 1. The A/D converter 100 in the circuit diagram of FIG. 2 includes the first integrator 101, the first quantizer 102, the first D/A converter 103, and the second D/A converter 113, among the constituent elements of the A/D converter 100 in FIG. 1.

The A/D converter 100 in FIG. 2 additionally includes a sampling capacitor 205, and switches 203, 204, 206, and 207.

The sampling capacitor 205 is connected between the input terminal 121 and the first integrator 101. Specifically, the sampling capacitor 205 has one end connected to the other end of the switch 206, and another end connected to respective ends of the switches 203 and 204.

Connection of an output node of the first D/A converter 103 (one end of a feedback capacitor 221) and an output node of the second D/A converter 113 (one end of a feedback capacitor 226) to the other end of the sampling capacitor 205 causes charges corresponding to an analog input signal, the first feedback signal F0 from the first D/A converter 103, and the third feedback signal F2 from the second D/A converter 113 to be stored in the other end of the sampling capacitor 205. In other words, this structure makes it possible to generate a signal obtained by adding to the analog input signal X, the first feedback signal F0 and the third feedback signal F2. Specifically, the sampling capacitor 205 functions as the adder 105.

The switch 203 is switched between ON and OFF according to a control signal Φ1, and has one end connected to the other end of the sampling capacitor 205, and another end to which a ground voltage is applied. The switch 204 is switched between ON and OFF according to a control signal Φ2, and has one end connected to the other end of the sampling capacitor 205, and another end connected to a minus terminal of an operational amplifier 201 included in the first integrator 101.

The switch 206 is switched between ON and OFF according to the control signal Φ1, and has one end connected to one end of the sampling capacitor 205, and another end connected to the input terminal 121 of the delta-sigma modulator 106. The switch 207 is switched between ON and OFF according to the control signal Φ2, and has one end connected to one end of the sampling capacitor 205, and another end to which a ground voltage is applied.

The switches 203, 204, 206, and 207 may be, for example, transistors or relays.

The first integrator 101 includes the operational amplifier 201 and an integral capacitor 202 as illustrated in FIG. 2. The operational amplifier 201 has (i) the minus terminal connected to the other end of the switch 204 and one end of the integral capacitor 202, (ii) an output terminal connected to the other end of the integral capacitor 202 and to a plus terminal of an operational amplifier included in the first quantizer 102, and (iii) a plus terminal to which a ground voltage is applied.

The first quantizer 102 includes the operational amplifier having (i) the plus terminal connected to the output terminal of the operational amplifier 201 included in the first integrator 101, (ii) a minus input terminal connected to a reference voltage terminal 235 that receives a reference voltage V_{comp}, and (iii) an output terminal connected to the first output terminal 122 of the first delta-sigma modulator 106. The first quantizer 102 compares a voltage of a signal output from the first integrator 101 with the reference voltage V_{comp}, and outputs (i) a signal whose voltage value is in a high level (abbreviated as “Hi”) when the signal output from the first integrator 101 is higher than the reference voltage V_{comp}, and (ii) a signal whose voltage value is in a low level (abbreviated as “Lo”) when the signal output from the first integrator 101 is lower than the reference voltage V_{comp}.

The first D/A converter 103 includes the feedback capacitor 221, switches 222 to 224, and reference voltage terminals 231 and 232. The feedback capacitor 221 has one end connected to the other end of the sampling capacitor 205. The switch 222 is switched between ON and OFF according to the control signal Φ1, and has one end connected to the other end of the feedback capacitor 221, and another end to which a ground voltage is applied. The switch 223 is switched between ON and OFF according to a control signal Φ2_Hi1, and has one end connected to the reference voltage terminal 231, and another end connected to the other end of the feedback capacitor 221. The switch 224 is switched between ON and OFF according to a control signal Φ2_Lo1, and has one end connected to the other end of the feedback capacitor 221, and another end connected to the reference voltage terminal 232. A reference voltage V_{REF} is applied to the reference voltage terminal 231, and a reference voltage −V_{REF} is applied to the reference voltage terminal 232. The switches 222, 223, and 224 may be, for example, transistors or relays.

The second D/A converter 113 includes a feedback capacitor 226, switches 227, 228, and 229, and reference voltage terminals 233 and 234. The feedback capacitor 226 has one end connected to the other end of the sampling capacitor 205. The switch 227 is switched between ON and OFF according to the control signal Φ1, and has one end connected to the other end of the feedback capacitor 226, and another end to which a ground voltage is applied. The switch 228 is switched between ON and OFF according to a control signal Φ2_Hi2, and has one end connected to the reference voltage terminal 233, and another end connected to the other end of the feedback capacitor 226. The switch 229 is switched between ON and OFF according to a control signal Φ2_Lo2, and has one end connected to the other end of the feedback capacitor 226, and another end connected to the reference voltage terminal 234. The reference voltage V_{REF} is applied to the reference voltage terminal 233, and the reference voltage −V_{REF} is applied to the reference voltage terminal 234. The switches 227, 228, and 229 may be, for example, transistors or relays.

### [1-4. Operations]

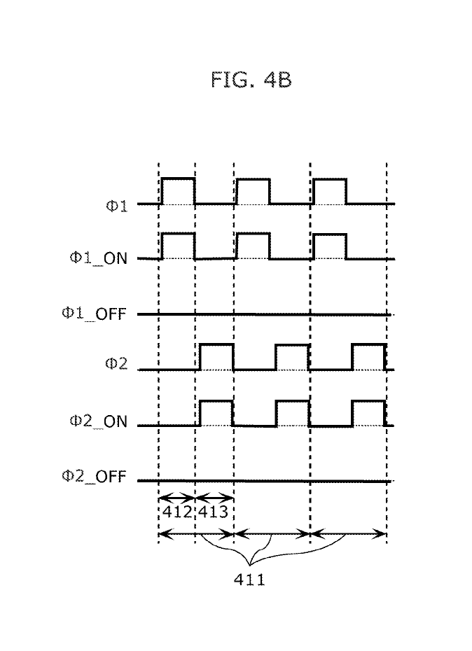

FIG. 4A is a timing chart of the control signals Φ1, Φ2, Φ2_ON1, Φ2_OFF1, Φ2_ON2, and Φ2_OFF2 of the switches. Here, one of the control signal Φ2_ON1 and the control signal Φ2_OFF1 is used as the control signals Φ2_Hi1 and Φ2_Lo1. Furthermore, one of the control signal Φ2_ON2 and the control signal Φ2_OFF2 is used as the control signals Φ2_Hi2 and Φ2_Lo2.

These are determined by the output of the first quantizer 102 and the second quantizer 112 per unit cycle 401. For example, when the output of the first quantizer 102 is high, the control signal Φ2_ON1 is used as the control signal Φ2_Hi1, and the control signal Φ2_OFF1 is used as the control signal Φ2_Lo1. When the output of the first quantizer 102 is low, the control signal Φ2_OFF1 is used as the control signal Φ2_Hi1, and the control signal Φ2_ON1 is used as the control signal Φ2_Lo1. When the output of the second quantizer 112 is high, the control signal Φ2_ON2 is used as the control signal Φ2_Hi2, and the control signal Φ2_OFF2 is used as the control signal Φ2_Lo2. When the output of the first quantizer 112 is low, the control signal Φ2_OFF is used as the control signal Φ2_Hi2, and the control signal Φ2_ON2 is used as the control signal Φ2_Lo2.

Each of the unit cycles 401 includes a sampling period 402 and a transfer period 403.

The sampling period 402 is a period during which the charges corresponding to the analog input signal X are stored in the sampling capacitor 205. During the sampling period 402, a voltage value (or logical value) of the control signal Φ1 is high, and a voltage value of the control signal Φ2 is low. Furthermore, the control signals Φ2_ON1, Φ2_OFF1, Φ2_ON2, and Φ2_OFF2 are low.

The transfer period 403 is a period during which charges obtained by adding charges corresponding to the signals output from the first quantizer 102 and the second quantizer 112 to the charges of the sampling capacitor 205 stored according to the analog input signal X are transferred to the integral capacitor 202. During the sampling period 403, a voltage value of the control signal Φ1 is low, and a voltage value of the control signal Φ2 is high. The control signals Φ1 and Φ2 are non-overlapping signals whose active periods (for example, high periods) do not overlap one another. The control signals Φ2_ON1 and Φ2_ON2 are high during the transfer period 403, in the same manner as the control signal Φ2. The control signals Φ2_OFF1 and Φ2_OFF2 remain low during the unit cycles 401. The unit cycle 401 is repeated.

Assume a case where the analog input signal X having a voltage value Vin is applied to the input terminal 121 in FIG. 2. When the voltage value of the control signal Φ1 is high during the sampling period 402, the switches 203, 206, 222, and 227 are ON. Here, the switches 204, 207, 223, 224, 228, and 229 are OFF. Charges Qs expressed by the following Expression 10 are stored in the sampling capacitor 205.

### [Math 10]

Q_{S}=C_{S}×Vₘ (Expression 10)

Since the switches 222 and 227 are ON and are connected to GND here, none of the charges is stored in the feedback capacitors 221 and 226.

When the sampling period 402 is over, it shifts to the transfer period 403. When the control signal Φ1 is low and the control signal Φ2 is high during the transfer period 403, the switches 204 and 207 are switched from OFF to ON. Here, the switches 203, 206, 222, and 227 are switched from ON to OFF. As such, the charges in the sampling capacitor 205 are transferred to the integral capacitor 202.

Furthermore, charges corresponding to the output signals from the first quantizer 102 and the second quantizer 112 are stored in the feedback capacitor 221 and the feedback capacitor 226, respectively, and the charges are transferred to the integral capacitor 202. Specifically, one of the switches 223 and 224 is turned ON according to the output value from the first quantizer 102. In other words, the voltage level of the control signal that controls the switches 223 and 224 is equal to the level corresponding to the signal output from the first quantizer 102. Furthermore, one of the switches 228 and 229 is turned ON according to the output value from the second quantizer 112. In other words, the voltage level of the control signal that controls the switches 228 and 229 is equal to the level corresponding to the signal output from the second quantizer 112.

Assuming that a ground voltage is applied to an input terminal of the operational amplifier 201, none of the charges is stored in the sampling capacitor 205. The feedback capacitor 221 stores (i) charges Q_{FB1} expressed in the following Expression 11a when the output of the first quantizer 102 is high, and (ii) charges Q_{FB1} expressed in the following Expression 11b when the output of the first quantizer 102 is low.

### [Math 11]

Q_{FB1}=C_{FB1}×V_{REF} (Expression 11a)

Q_{FB1}=−C_{FB1}×V_{REF} (Expression 11b)

The feedback capacitor 226 stores (i) charges Q_{FB3} expressed in the following Expression 12a when the output of the second quantizer 112 is high, and (ii) charges Q_{FB3} expressed in the following Expression 12b when the output of the second quantizer 112 is low.

### [Math 12]

Q_{FB3}=C_{FB3}×V_{REF} (Expression 12a)

Q_{FB3}=−C_{FB1}×V_{REF} (Expression 12b)

Expressions 11a and 12a yield positive values, and Expressions 11b and 12b yield negative values. In other words, the first D/A converter 103 and the second D/A converter 113 can yield both positive and negative values. This type of D/A converters are bipolar. In contrast, D/A converters that output one of positive and negative values are unipolar.

As illustrated in FIG. 4A, the switches are repeatedly switched between ON and OFF based on the control signals Φ1, Φ2, Φ2_ON1, Φ2_OFF1, Φ2_ON2, and Φ2_OFF2. Accordingly, the charges are transferred to the integral capacitor 202 per unit cycle 401.

In summary, charges Q_{I} added to the integral capacitor 202 during the transfer periods 403 are expressed by the following Expression 13.

### [Math 13]

ΣQ₁=ΣQ_{S}−ΣQ_{FB1}−ΣQ_{FB3} (Expression 13)

Here, the charges Q_{FB1} transferred per unit cycle 401 correspond to the first feedback signal F0. Furthermore, the charges Q_{FB3} correspond to the third feedback signal F2. According to Expression 13, the voltage to be applied to the integral capacitor 202 is expressed by the following Expression 14.

### [Math 14]

$${V}_{I} = \frac{1}{{C}_{I}} \times \sum {Q}_{I} \qquad ( Expression 14 )$$

The voltage V_{I} in Expression 14 is an output voltage from the first integrator 101, and an input voltage to the first quantizer 102. The first quantizer 102 compares the voltage V_{I} with a threshold voltage to be generated with reference to the reference voltage V_{COMP}, and outputs a digital signal.

### [1-5. Variations of D/A Converters]

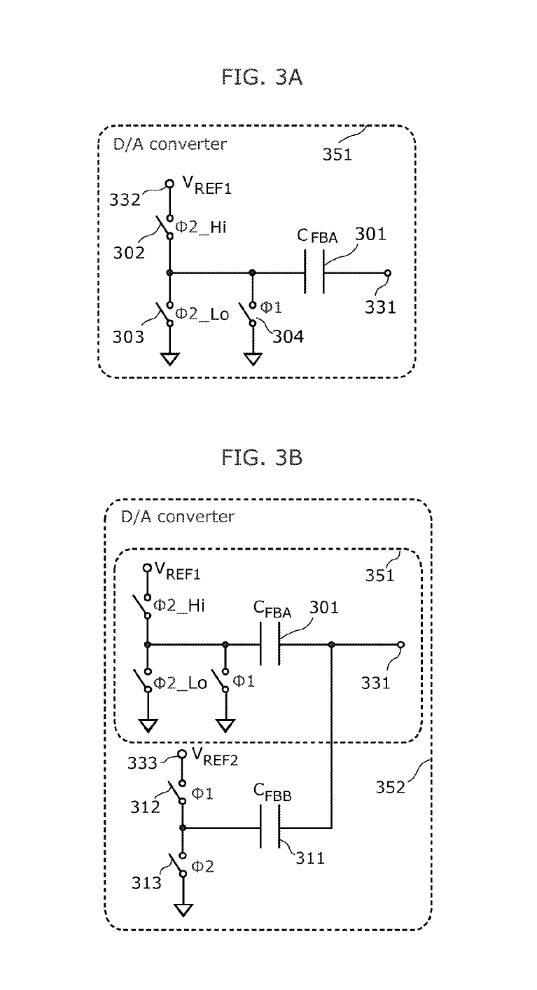

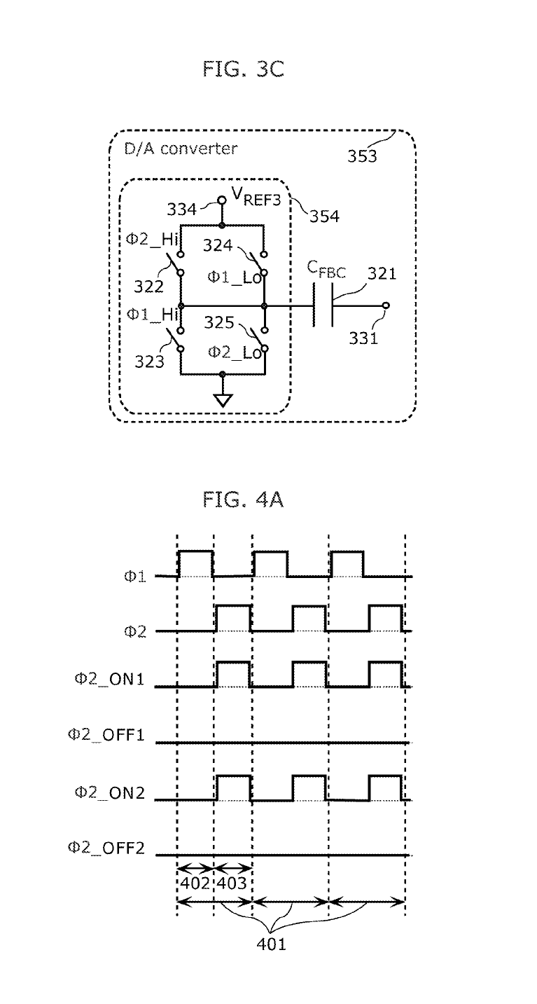

FIGS. 3A to 3C are circuit diagrams illustrating another configuration of the first D/A converter 103 or the second D/A converter 113 in FIG. 2. Since the first D/A converter 103 in the first delta-sigma modulator 106 receives an input signal of either 0 or a positive value, the first D/A converter 103 may be unipolar or bipolar, which will be described in detail in 1-5-4. In contrast, since the delta-sigma modulators at the second or subsequent stages receive an input signal representing a quantization error in the previous delta-sigma modulator, the input signal needs to have both positive and negative values. Thus, each of the delta-sigma modulators at the second or subsequent stages desirably includes a bipolar D/A converter.

### [1-5-1. Example of Unipolar D/A Converter]

A D/A converter 351 in FIG. 3A is unipolar, and can be used as the first D/A converter 103.

The D/A converter 351 includes a feedback capacitor 301, switches 302 to 304, and a reference voltage terminal 332 as illustrated in FIG. 3A. The feedback capacitor 301 has one end connected to a D/A-converter output terminal 331. The switch 302 is switched between ON and OFF according to the control signal Φ2_Hi, and has one end connected to the reference voltage terminal 332, and another end connected to the other end of the feedback capacitor 301. The switch 303 is switched between ON and OFF according to the control signal Φ2_Lo, and has one end connected to the other end of the feedback capacitor 301, and another end to which a ground voltage is applied. The switch 304 is switched between ON and OFF according to the control signal Φ1, and has one end connected to the other end of the feedback capacitor 301, and another end to which a ground voltage is applied.

Assume a case where the first D/A converter 103 is replaced with the D/A converter 353. For example, when the output of the first quantizer 102 is high, the control signal Φ2_ON1 is used as the control signal Φ2_Hi, and the control signal Φ2_OFF1 is used as the control signal Φ2_Lo. When the output of the first quantizer 102 is low, the control signal Φ2_OFF1 is used as the control signal Φ2_Hi, and the control signal Φ2_ON1 is used as the control signal Φ2_Lo. These are determined by the output of the first quantizer 102 per unit cycle 401. Furthermore, the D/A converter 351 is connected to GND, in replacement of application of the reference voltage −V_{REF} to the reference voltage terminal 232 of the first D/A converter 103 in FIG. 2. The feedback capacitor 301 stores (i) charges Q_{FBA} expressed in the following Expression 15a when the output from the first quantizer 102 is high, and (ii) charges Q_{FBA} expressed in the following Expression 15b when the output from the first quantizer 102 is low.

### [Math 15]

Q_{FBA}=C_{FBA}×V_{REF1} (Expression 15a)

Q_{FBA}=0 (Expression 15b)

Expressions 15a and 15b indicate that the D/A converter 351 operates only to reduce charges from the feedback capacitor 301. In other words, the D/A converter 351 in FIG. 3A is unipolar.

### [1-5-2. Example 1 of Bipolar D/A Converter]

The D/A converter 352 in FIG. 3B is a bipolar D/A converter, and can be used as at least one of the first D/A converter 103 and the second D/A converter 113.

The D/A converter 352 includes a feedback capacitor 311, switches 312 and 313, and a reference voltage terminal 333, in addition to the D/A converter 351 (unipolar D/A converter circuit) in FIG. 3A. The feedback capacitor 311 has one end connected to the D/A-converter output terminal 331. The switch 312 is switched between ON and OFF according to the control signal Φ1, and has one end connected to the reference voltage terminal 333, and another end connected to the other end of the feedback capacitor 311. The switch 313 is switched between ON and OFF according to the control signal Φ2, and has one end connected to the other end of the feedback capacitor 311, and another end to which a ground voltage is applied.

Assume a case where the first D/A converter 103 is replaced with the D/A converter 352, for example. The feedback capacitor 311 is only connected to the switches controlled by the control signals Φ1 and Φ2. Thus, the quantity of charges transferred from the feedback capacitor 311 is constant, independent from the output of the first quantizer 102. Charges Q_{FBB} expressed by the following Expression 16 are stored in the feedback capacitor 311 during the sampling period.

### [Math 16]

Q_{FBB}=C_{FBB}×V_{REF2} (Expression 16)

Expressions 15a and 15b express the quantity of charges Q_{FBA} stored in the feedback capacitor 301 during the transfer period 403, and Expression 16 expresses the quantity of charges Q_{FBB} stored in the feedback capacitor 311 during the sampling period 402. The difference between Q_{FBA} and Q_{FBB} is transferred from an output terminal of the D/A converter 352 to the first integrator 101 per unit cycle 401. Expressions 15a and 15b and Expression 16 give (i) Expression 17a when the output of the first quantizer 102 is high, and (ii) Expression 17b when the output of the first quantizer 102 is low.

### [Math 17]

Q_{FBA}−Q_{FBB}=C_{FBA}×V_{REF1}−C_{FBB}×V_{REF1} (Expression 17a)

Q_{FBA}−Q_{FBB}=−C_{FBB}×V_{REF2} (Expression 17b)

If the following Expression 18 holds, Expressions 17a and 17b can yield both positive and negative values.

### [Math 18]

C_{FBA}×V_{REF1}>C_{FBB}×V_{REF2} (Expression 18)

In other words, the D/A converter 352 is bipolar. When the D/A converter 352 is used as the first D/A converter 103, the D/A converter 352 may be used as a unipolar D/A converter without satisfying Expression 18.

### [1-5-3. Example 2 of Another Bipolar D/A Converter]

A D/A converter 353 in FIG. 3C is a bipolar D/A converter, and can be used as at least one of the first D/A converter 103 and the second D/A converter 113.

The D/A converter 353 includes a feedback capacitor 321, a switch unit 354, and a reference voltage terminal 334.

The feedback capacitor 321 has one end connected to the D/A-converter output terminal 331.

The switch unit 354 includes switches 322 to 325. The switch 322 is switched between ON and OFF according to the control signal Φ2_Hi, and has one end connected to the reference voltage terminal 334, and another end connected to an output node of the switch unit 354. The output node is a node connected to the other end of the feedback capacitor 321 in FIG. 3C. The switch 323 is switched between ON and OFF according to the control signal Φ1_Hi, and has one end connected to the output node of the switch unit 354, and another end to which a ground voltage is applied. The switch 324 is switched between ON and OFF according to the control signal Φ1_Lo, and has one end connected to the reference voltage terminal 334, and another end connected to the output node of the switch unit 354. The switch 325 is switched between ON and OFF according to the control signal Φ2_Lo, and has one end connected to the output node of the switch unit 354, and another end to which a ground voltage is applied.

Assume a case where the first D/A converter 103 is replaced with the D/A converter 353.

FIG. 4B is a timing chart illustrating these signal operations. Here, one of the control signals Φ1_ON and Φ1_OFF is used as the control signals Φ1_Hi and Φ1_Lo1. For example, when the output of the first quantizer 102 is high, the control signal Φ1_ON is used as the control signal Φ1_Hi, and the control signal Φ1_OFF is used as the control signal Φ1_Lo. When the output of the first quantizer 102 is low, the control signal Φ1_OFF is used as the control signal Φ1_Hi, and the control signal Φ1_ON is used as the control signal Φ1_Lo. Furthermore, one of the control signals Φ2_ON and Φ2_OFF is used as the control signals Φ2_Hi and Φ2_Lo. When the output of the first quantizer 102 is high, the control signal Φ2_ON is used as the control signal Φ2_Hi, and the control signal Φ2_OFF is used as the control signal Φ2_Lo. When the output of the first quantizer 102 is low, the control signal Φ2_OFF is used as the control signal Φ2_Hi, and the control signal Φ2_ON is used as the control signal Φ2_Lo. These are determined by the output of the first quantizer 102 per unit cycle 411.

Each of the unit cycles 411 includes a sampling period 412 and a transfer period 413 similarly as FIG. 4A. The control signal Φ1_ON is high during the sampling period 412, and is low during the transfer period 413 as the control signal Φ1. The control signal Φ2_ON is low during the sampling period 412, and is high during the transfer period 413 as the control signal Φ2. The control signals Φ1_OFF and Φ2_OFF remain low during the unit cycles 411. The unit cycle 411 is repeated.

A difference Q_{FBC} between the quantity of charges stored in the feedback capacitor 321 during the transfer period 413 and the quantity of charges stored in the feedback capacitor 321 during the sampling period 412 is transferred from an output terminal of the D/A converter 353 to the first integrator 101 per unit cycle 411. The feedback capacitor 321 stores (i) charges Q_{FBC} expressed in the following Expression 19a when the output of the first quantizer 102 is high, and (ii) charges Q_{FBC} expressed in the following Expression 19b when the output of the first quantizer 102 is low.

### [Math 19]

Q_{FBC}=C_{FBC}×V_{REF3} (Expression 19a)

Q_{FBC}=−C_{FBC}×V_{REF3} (Expression 19b)

Expressions 19a and 19b indicate that the D/A converter 353 is bipolar.

The first D/A converter 103 and the second D/A converter 113 in FIG. 2 use the reference voltages V_{REF} and V_{REF}. Although the D/A converter 352 in FIG. 3B and the D/A converter 353 in FIG. 3C are bipolar, they use not the reference voltage −V_{REF} but the reference voltage V_{REF}. In other words, the D/A converter 352 in FIG. 3B and the D/A converter 353 in FIG. 3C do not require the reference voltage −V_{REF}, and function as bipolar D/A converters with one-sided power supply.

### [1-5-4. Application of Variations of D/A Converters]

FIGS. 2, and 3A to 3C hereinbefore specifically illustrate bipolar and unipolar D/A converters. As described above, the bipolar and unipolar D/A converters can be separately used depending on a range of values to be indicated by an input signal. When the signal input to the delta-sigma modulator indicates both positive and negative values, the D/A converter in the delta-sigma modulator is desirably bipolar. In contrast, when the signal input to the delta-sigma modulator indicates positive or negative values including 0, the D/A converter in the delta-sigma modulator may be unipolar.

The signal input to the second delta-sigma modulator 116 is a quantization error introduced by the first delta-sigma modulator 106. The quantization error has both positive and negative values. Thus, when a unipolar D/A converter is used in the second delta-sigma modulator 116, the second feedback signal F1 indicates one of positive and negative values, and a difference between the range of the input signal and the range of the second feedback signal F1 increases. As a result, the negative feedback loop of the second delta-sigma modulator 116 does not normally operate, and easily becomes overloaded. This causes a larger error when an analog input signal is converted into a digital signal.

The third feedback signal F2 desirably has both positive and negative values. For example, assume a case where the first feedback signal F0 and the third feedback signal F2 have positive values larger than or equal to 0 or negative values smaller than or equal to 0. Here, when the input signal is 0 or closer, the loop easily becomes overloaded, and the error in A/D conversion easily becomes larger. The third feedback signal F2 having both positive and negative values offsets the input signal. Thus, adjusting the offset value negates the need to use the input signal in a range where the error increases.

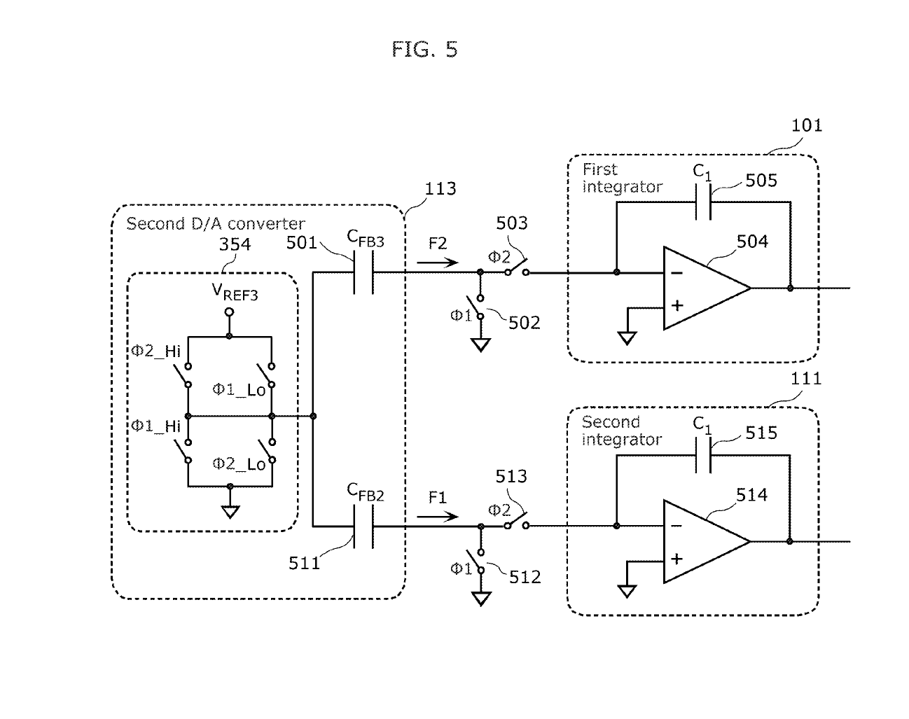

FIG. 5 is a circuit diagram schematically illustrating a configuration of the second D/A converter 113 as a bipolar D/A converter. In FIG. 5, the A/D converter 100 includes the first integrator 101, the second integrator 111, the second D/A converter 113, and switches 502, 503, 512, and 513.

The first integrator 101 includes an operational amplifier 504 and an integral capacitor 505 similarly as the configuration of the first integrator 101 in FIG. 2. The operational amplifier 504 has (i) a minus terminal connected to the other end of the switch 503 and to one end of the integral capacitor 505, (ii) an output terminal connected to the other end of the integral capacitor 505 and to an input terminal of the first quantizer 102, and (iii) a plus terminal to which a ground voltage is applied.

The second integrator 111 includes an operational amplifier 514 and an integral capacitor 515 similarly as the configuration of the first integrator 101. The operational amplifier 514 has (i) a minus terminal connected to the other end of the switch 513 and to one end of the integral capacitor 515, (ii) an output terminal connected to the other end of the integral capacitor 515 and to an input terminal of the second quantizer 112, and a plus terminal to which a ground voltage is applied.

The second D/A converter 113 is constructed based on the D/A converter 353 in FIG. 3C, and includes the switch unit 354 in FIG. 3C, and feedback capacitors 501 and 511. The switch unit 354 has an output node connected to each end of the feedback capacitors 501 and 511. The feedback capacitor 501 has one end connected to the output node of the switch unit 354, and another end connected to each end of the switches 502 and 503. The feedback capacitor 511 has one end connected to the output node of the switch unit 354, and another end connected to each end of the switches 512 and 513. The switch unit 354 operates according to the output signal from the second quantizer 112, in accordance with the timing chart in FIG. 4B. The circuit in FIG. 5 requires the feedback capacitor 501 for outputting the third feedback signal F2 and the feedback capacitor 511 for outputting the second feedback signal F1. Furthermore, the switch unit 354 may be shared between the third feedback signal F2 and the second feedback signal F1 as illustrated in FIG. 5.

The switch 502 is switched between ON and OFF according to the control signal Φ1, and has one end connected to the other end of the feedback capacitor 501, and another end to which a ground voltage is applied.

The switch 503 is switched between ON and OFF according to the control signal Φ2, and has one end connected to the other end of the feedback capacitor 501, and another end connected to the minus terminal of the operational amplifier 504 in the first integrator 101 and to one end of the integral capacitor 505. The switch 512 is switched between ON and OFF according to the control signal Φ1, and has one end connected to the other end of the feedback capacitor 511 of the second D/A converter 113, and another end to which a ground voltage is applied. The switch 513 is switched between ON and OFF according to the control signal Φ2, and has one end connected to the other end of the feedback capacitor 511, and another end connected to the minus terminal of the operational amplifier 514 in the second integrator 111 and to one end of the integral capacitor 515.

As described above, when the input signal indicates positive values including 0 or negative values including 0, the first D/A converter 103 is desirably unipolar and the second D/A converter 113 is desirably bipolar. Accordingly, the negative feedback loop of the second delta-sigma modulator 116 hardly becomes overloaded.

Furthermore, this setting equates to assigning an offset value to an input signal to be input to the first delta-sigma modulator 106. Thus, the error in A/D conversion becomes smaller.

When the signal to be input to the input terminal 121 excludes a range having a larger error, such as a range of values closer to 0, the third feedback signal F2 may be positive or negative values, that is, does not have to include 0.

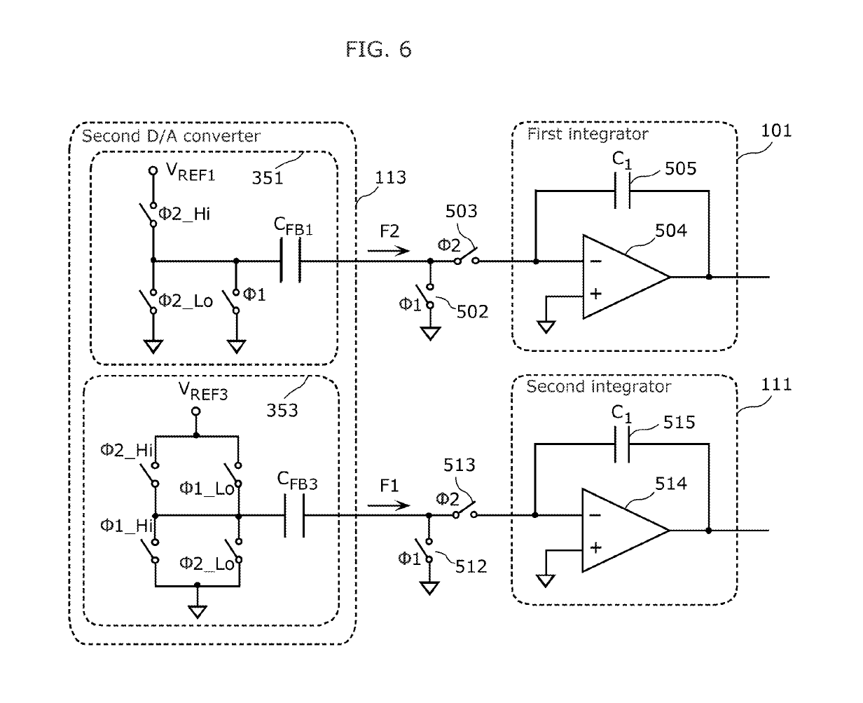

FIG. 6 is a circuit diagram schematically illustrating an example configuration of the second D/A converter 113 functioning as both bipolar and unipolar D/A converters. In FIG. 6, the A/D converter 100 includes the first integrator 101, the second integrator 111, the second D/A converter 113, and the switches 502, 503, 512, and 513. The configuration of the first integrator 101, the second integrator 111, and the switches 502, 503, 512, and 513 are the same as those in FIG. 5.

The second D/A converter 113 in FIG. 6 includes the D/A converter 351 that is unipolar, and the D/A converter 353 that is bipolar. The configuration of the D/A converter 351 is the same as that of the D/A converter 351 in FIG. 3A, and one end of the feedback capacitor is connected to each end of the switches 502 and 503. The configuration of the D/A converter 353 is the same as that of the D/A converter 353 in FIG. 3C, and one end of the feedback capacitor is connected to each end of the switches 512 and 513. The switches in the second D/A converter 113 operate according to the output signal from the second quantizer 112, in accordance with the timing charts in FIGS. 4A and 4B. In this configuration of the second D/A converter 113, the second feedback signal F1 has both positive and negative values, whereas the third feedback signal F2 has positive or negative values (does not include 0).

As described above, when the input signal has positive or negative values and excludes an input range having a larger error, a unipolar D/A converter may be used as the first D/A converter 103, and a D/A converter functioning both as a bipolar D/A converter for the second feedback signal F1 and as a unipolar D/A converter for the third feedback signal F2 may be used as the second D/A converter 113. Accordingly, the negative feedback loop of the first delta-sigma modulator 106 and the second delta-sigma modulator 116 hardly becomes overloaded. Thus, the error in A/D conversion becomes smaller.

### [1-6. Variations of Integrator (Operations of Incremental A/D Converter]

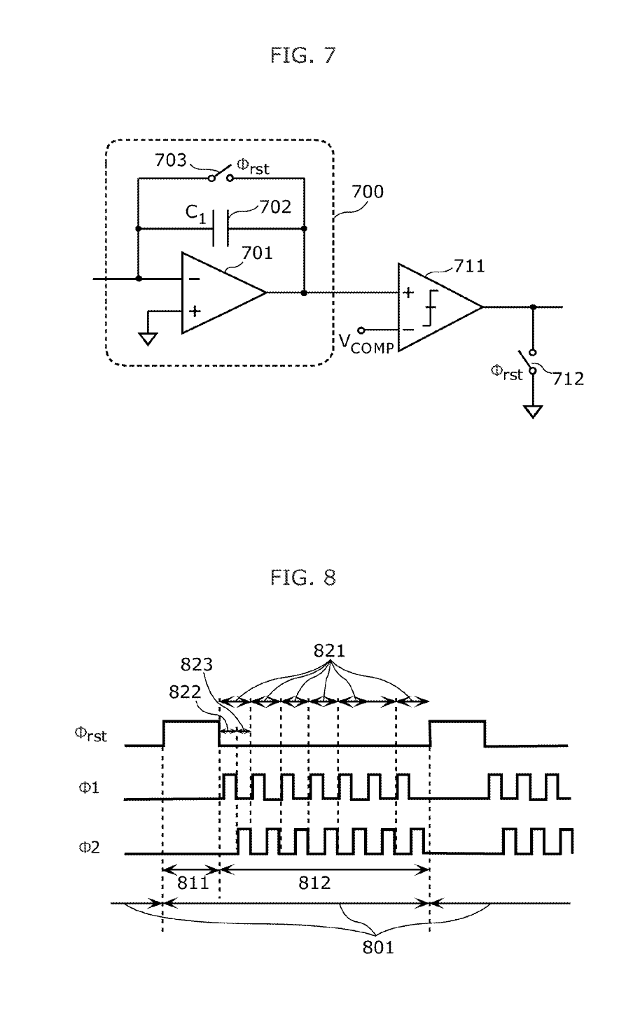

Furthermore, variations of the A/D converter 100 include, for example, an incremental A/D converter. The operations of the incremental A/D converter will be described with reference to FIGS. 7 and 8.

FIG. 7 is a circuit diagram exemplifying an integrator and a quantizer according to a variation of the present disclosure. The A/D converter in FIG. 7 only illustrates an integrator 700, a quantizer 711, and a switch 712.

The integrator 700 according to the variation can be used not only as the first integrator 101 but also as the second integrator 111 in FIG. 1. The integrator 700 includes an operational amplifier 701, an integral capacitor 702, and a switch 703. The operational amplifier 701 has (i) a minus terminal connected to an input node of the integrator 700 and each end of the integral capacitor 702 and the switch 703, (ii) an output terminal connected to the output node and the other end of each of the integral capacitor 702 and the switch 703, and (iii) a plus terminal to which a ground voltage is applied. The switch 703 is a reset switch, and is switched between ON and OFF according to a reset signal Φᵣₛₜ.

The quantizer 711 is an operational amplifier, and has (i) a plus terminal connected to the output node of the integrator 700, (ii) an output terminal connected to one end of the switch 712, and (iii) a minus terminal to which the reference voltage V_{COMP} is applied.

The switch 712 is a reset switch that is switched between ON and OFF according to the reset signal Φᵣₛₜ, and has one end connected to the output terminal of the quantizer 711, and another terminal to which a ground voltage is applied.

The A/D converter 100 with such a configuration allows the switches 703 and 712 in FIG. 7 to be ON by controlling the reset signal Φᵣₛₜ during a reset period. With both ends of the integral capacitor 702 short-circuited, the charges in the integral capacitor 702 become 0. Furthermore, with the switch 712 turned ON, the output of the quantizer 711 is set low. The switches 703 and 712 for reset may be connected to the others.

FIG. 8 is a timing chart of control signals of switches in an incremental A/D converter according to the variation. Each A/D conversion cycle 801 includes a reset period 811 and an A/D conversion period 812. The A/D conversion period 812 is a period during which a unit cycle 821 is repeated M times. Each of the unit cycles 821 includes a sampling period 822 and a transfer period 823. The operations during the sampling period 822 and the transfer period 823 are basically the same as those during the sampling period 402 and the transfer period 403, respectively, in FIG. 4A.

During the reset period 811, the reset signal Φᵣₛₜ is high, and the control signals Φ1 and Φ2 are low. During the A/D conversion period 812, the reset signal Φᵣₛₜ is low, and the control signals Φ1 and Φ2 alternate between high and low as described with reference to FIG. 4. After the A/D conversion period 812, the control signals shift to the next reset period 811 of the A/D conversion cycle 801. As described above, the same operations under the reset period 811 and the A/D conversion period 812 are repeated as the A/D conversion cycle 801.

### [1-7. Advantages and Others]

According to Embodiment 1, the negative feedback structure can make a mismatch in transfer function between delta-sigma modulators and a digital filter less sensitive.

In order to demonstrate the advantages according to Embodiment 1, the characteristics are compared when the op-amp gain of the integrator decreases from infinity (ideal condition) to approximately 40 dB.

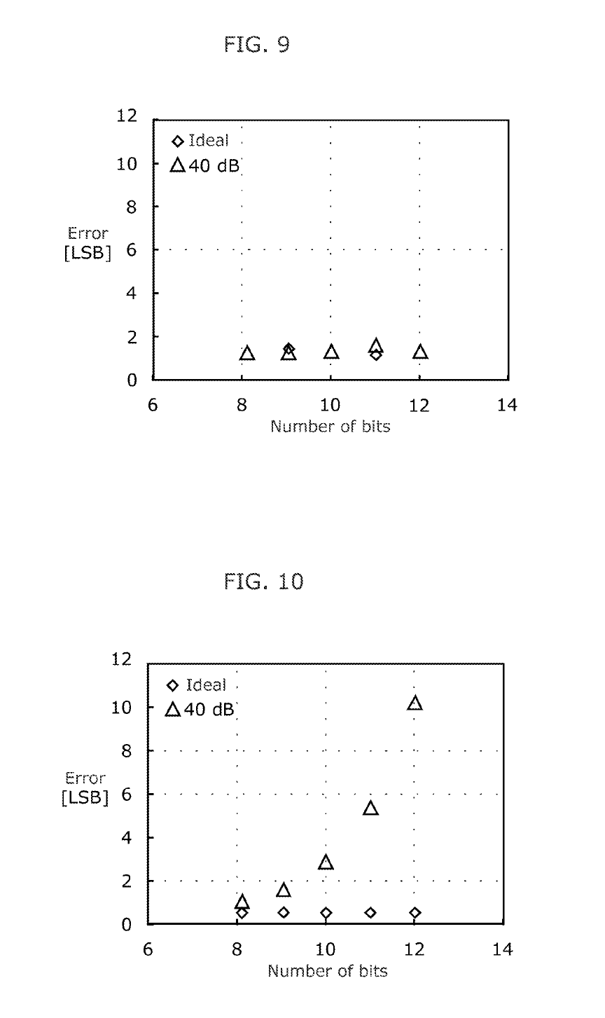

FIG. 9 is a graph plotting the maximum linear approximation error for each number of bits in A/D conversion, using the incremental A/D converter according to Embodiment 1. Furthermore, FIG. 10 graphs a result of such plotting using a conventional device without any third feedback signal F2. The number of bits can be changed according to the number of the unit cycles 821.

As graphed in FIG. 10, when the operational amplifier ideally operates, the error is 0.5 least significant bit (LSB) regardless of the number of bits. In contrast, when the op-amp gain is 40 dB, as the number of bits increases, the error also increases. For example, when the number of bits is 12, the error is approximately 10 LSB, indicating that the accuracy decreases by approximately 3 bits.

In FIG. 9, there is not much difference in error between when the operational amplifier ideally operates and when the gain is 40 dB, that is, the error ranging from 1 to 1.5 LSB. In other words, decrease in the accuracy in A/D conversion according to decrease in the op-amp gain in FIG. 10 is minimized in FIG. 9. In the incremental A/D converter according to Embodiment 1, the third feedback signal F2 suppresses characteristic degradation in the op-amp gain.

As described above, the A/D converter 100 according to Embodiment 1 includes: the first integrator 101 that integrates a signal obtained by adding the first feedback signal F0 and the third feedback signal F2 to an analog input signal, to generate a first output signal; a first quantizer 102 that converts the first output signal into a first digital signal; a first D/A converter 103 that converts the first digital signal into a first analog signal; a second integrator 111 that integrates a signal obtained by adding the first analog signal and a second feedback signal F1 to the first output signal, to generate a second output signal; a second quantizer 112 that converts the second output signal into a second digital signal; and a second D/A converter 113 that converts the second digital signal into a second analog signal, wherein the first feedback signal F0 is the first analog signal, the second feedback signal F1 is the second analog signal, and the third feedback signal F2 is the second analog signal.

When the conventional A/D converter having no third feedback signal F2 ideally operates, the quantization error E1 introduced by the delta-sigma modulator at the first stage can be canceled by the digital filter at the latter stage, resulting in obtainment of high-accuracy A/D conversion characteristics.

In practice, the quantization error E1 cannot be canceled because each element in the A/D converter does not ideally operates due to the error caused by the difference in characteristics between the elements (error that is induced by the hardware construction and does not appear in the expressions) or depending on a degree of degradation in the op-amp gain, etc. Specifically, when the op-amp gain in the integrator decreases, error component is added to Expressions 1 and 6 that are transfer functions of the integrator. When the coefficients of the digital filter in Expressions 4a and 4b and 8a and 8b are constant, the term of the quantization error E1 is not completely offset as expressed in Expressions 5 and 9. This is caused by the hardware-induced mismatch in transfer function between the delta-sigma modulators and the digital filter. This mismatch may decrease the accuracy in the conventional A/D converter.

In contrast, the negative feedback structure for feeding back the third feedback signal F2 from the delta-sigma modulator at the last stage to the delta-sigma modulator at the first stage allows the A/D converter 100 according to Embodiment 1 to operate to reduce the term of the quantization error E1 that remains by the mismatch. In other words, the A/D converter 100 according to Embodiment 1 feeds back the total variation in the device using the third feedback signal F2. Here, the feedback operation suppresses the error indicated by the feedback signal used in the feedback operation. Thus, the A/D converter 100 according to Embodiment 1 can perform the feedback operation for addressing the error caused by the total variation in the device, that is, the error remaining by the mismatch, by inputting the feedback signal from the delta-sigma modulator at the last stage to the delta-sigma modulator at the first stage. Thus, the high-accuracy A/D converter 100 can be provided. Furthermore, the A/D converter 100 can retain high linearity.

Furthermore, in the A/D converter 100, the analog input signal X has a constantly higher than or equal to 0 or constantly lower than or equal to 0, and the second feedback signal F1 may be bipolar according to Embodiment 1.

Such a structure suppresses overload to the feedback loop at the second stage, and decrease in the error in the A/D conversion. Thus, the high-accuracy A/D converter 100 can be provided.

Furthermore, in the A/D converter 100, the third feedback signal F2 may be bipolar according to Embodiment 1.

With such a structure, the input range with less error in the A/D conversion is available. Thus, the high-accuracy A/D converter 100 can be provided.

Furthermore, the A/D converter 100 may be an incremental A/D converter according to Embodiment 1.

Such a structure suppresses decrease in error caused by the mismatch in transfer function between delta-sigma modulators and a digital filter in the A/D conversion, while the A/D converter 100 retains high linearity. Thus, the high-accuracy A/D converter 100 can be provided.

### Embodiment 2

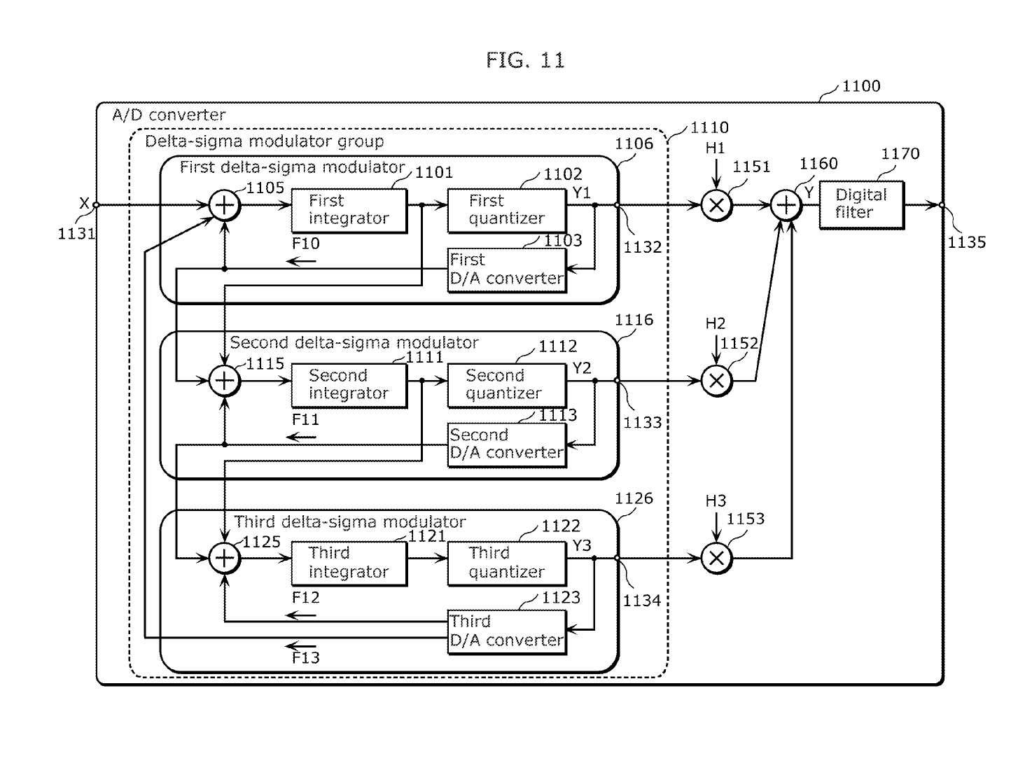

Embodiment 2 will be described with reference to FIG. 11. Although Embodiment 1 describes the delta-sigma modulators at two stages, Embodiment 2 describes delta-sigma modulators at three stages.

### [2-1. Structure]

FIG. 11 is a functional block diagram of an A/D converter 1100 according to Embodiment 2.

The A/D converter 1100 includes a delta-sigma modulator group 1110, multipliers 1151 to 1153, an adder 1160, a digital filter 1170, an input terminal 1131, and an output terminal 1135.

The delta-sigma modulator group 1110 includes delta-sigma modulators at three stages, that is, a first delta-sigma modulator 1106 at the first stage, a second delta-sigma modulator 1116 at the second stage, and a third delta-sigma modulator 1126 at the third stage, all of which are cascaded.

The first delta-sigma modulator 1106 will be hereinafter described. The first delta-sigma modulator 1106 includes an adder 1105, a first integrator 1101, a first quantizer 1102, a first D/A converter 1103, and a first output terminal 1132.

The adder 1105 adds, to an analog input signal applied to an input terminal 1131, a first feedback signal F10 generated by the first delta-sigma modulator 1106 and a fourth feedback signal F13 generated by the third delta-sigma modulator 1126.

The first integrator 1101 is a circuit that that evaluates a first integral by integrating a signal output from the adder 1105 to output an analog signal.

The first quantizer 1102 is a circuit that performs a first quantization by quantizing the analog signal output from the first integrator 1101 into a digital signal. The first quantizer 1102 outputs the generated digital signal to the first output terminal 1132 and the first D/A converter 1103.

The first D/A converter 1103 is a circuit that performs a first D/A conversion by converting the digital signal output from the first quantizer 1102 into the first feedback signal F10 that is an analog signal. The first feedback signal F10 is fed back to an input terminal of the first integrator 1101 through the adder 1105. Furthermore, the first feedback signal F10 is output to the delta-sigma modulator at the next stage.

The structure of the second delta-sigma modulator 1116 will be hereinafter described. The second delta-sigma modulator 1116 includes an adder 1115, a second integrator 1111, a second quantizer 1112, a second D/A converter 1113, and a second output terminal 1133.

The adder 1115 adds the output signal from the first integrator 1101, the first feedback signal F10 output from the first D/A converter 1103, and a second feedback signal F11 output from the second D/A converter 1113 in the second delta-sigma modulator 1116.

The second integrator 1111 is a circuit that that performs a second integral by integrating a signal output from the adder 1115 to generate an analog signal.

The second quantizer 1112 is a circuit that performs a second quantization by quantizing the analog signal output from the second integrator 1111 into a digital signal. The second quantizer 1112 outputs the generated digital signal to the second output terminal 1133 and the second D/A converter 1113.

The second D/A converter 1113 is a circuit that performs a second D/A conversion by converting the digital signal output from the second quantizer 1112 into the second feedback signal F11 that is an analog signal. As described above, the second feedback signal F11 is fed back to an input terminal of the second integrator 1111 through the adder 1115. Furthermore, the second feedback signal F11 is output to the third delta-sigma modulator 1126.

The structure of the third delta-sigma modulator 1126 will be hereinafter described. The third delta-sigma modulator 1126 includes an adder 1125, a third integrator 1121, a third quantizer 1122, a third D/A converter 1123, and a third output terminal 1134.

The adder 1125 adds the output signal from the second integrator 1111, the second feedback signal F11 output from the second D/A converter 1113, and a third feedback signal F12 output from the third D/A converter 1123 in the third delta-sigma modulator 1126.

The third integrator 1121 is a circuit that evaluates a third integral by integrating a signal output from the adder 1125 to generate a signal.

The third quantizer 1122 is a circuit that performs a third quantization by quantizing the signal output from the third integrator 1121 into a digital signal. The third quantizer 1122 outputs the digital signal to the third output terminal 1134 and the third D/A converter 1123.

The third D/A converter 1123 is a circuit that performs a third D/A conversion by converting the digital signal output from the third quantizer 1122 into the third feedback signal F12 and the fourth feedback signal F13 that are analog signals. As described above, the second feedback signal F12 is fed back to an input terminal of the third integrator 1121 through the adder 1125. Furthermore, the fourth feedback signal F13 is fed back to the input terminal of the first integrator 1101. The third feedback signal F12 and the fourth feedback signal F13 may be the same signal.

The A/D converter 1100 according to Embodiment 2 may generate a fifth feedback signal (not illustrated) output from the second D/A converter 1113 and a sixth feedback signal (not illustrated) output from the third D/A converter 1123. The fifth feedback signal is a signal fed back to the input terminal of the first integrator 1101. Furthermore, the sixth feedback signal is a signal fed back to the input terminal of the second integrator 1111. Furthermore, the fourth feedback signal may be replaced with the fifth and sixth feedback signals.

The multiplier 1151 is a circuit that multiplies an output signal Y1 from the first delta-sigma modulator 1106 with a coefficient H1. The multiplier 1152 is a circuit that multiplies an output signal Y2 from the second delta-sigma modulator 1116 with a coefficient H2. The multiplier 1153 is a circuit that multiplies an output signal Y3 from the third delta-sigma modulator 1126 with a coefficient H3. The adder 1160 is a circuit that adds digital signals output from the multipliers 1151 to 1153. A method for deriving the coefficients H1 to H3 will be described later. In summary, the coefficients H1 to H3 are derived to cancel the quantization error in the first delta-sigma modulator 1106.

The digital filter 1170 includes a low-pass filter and a decimation filter that are example band-pass filters, similarly as the digital filter 150 according to Embodiment 1. The low-pass filter outputs a signal obtained by removing or reducing a signal component at a predetermined frequency or higher, among the signals input to the adder 1160. The digital filter 1170 may include other filters than the low-pass filter and the decimation filter.

### [2-2. Operations]

The operations of the A/D converter 1100 in FIG. 11 will be hereinafter described. Here, the first integrator 1101, the second integrator 1111, and the third integrator 1121 are single integrators.

X denotes a signal to be input to the input terminal 1131, E1 denotes quantization noise introduced by the first quantizer 1102, E2 denotes quantization noise introduced by the second quantizer 1112, E3 denotes quantization noise introduced by the third quantizer 1122, Y1 denotes a first output signal from the first quantizer 1102, Y2 denotes a second output signal from the second quantizer 1112, and Y3 denotes a third output signal from the third quantizer 1122. According to Expression 1, transfer functions of the output signals Y1, Y2, and Y3 are expressed as the following Expressions 20a, 20b, and 20c, respectively.

### [Math 20]

Y1=Z⁻¹×(X−Y3)+(1−Z⁻¹)×E1 (Expression 20a)

Y2=−Z⁻¹×E1+(1−Z⁻¹)×E2 (Expression 20b)

Y3=−Z⁻¹×E2+(1−Z⁻¹)×E3 (Expression 20c)

The multipliers 1151, 1152, and 1153 multiply the first output signal Y1, the second output signal Y2, and the third output signal Y3 with the coefficients H1, H2, and H3, respectively. The adder 1160 is a circuit that adds the signals output from the multipliers 1151 to 1153 to generate a digital signal Y. The digital signal Y is expressed by the following Expression 21.

### [Math 21]

Y=H1×Y1+H2×Y2+H3×Y3 (Expression 21)

Here, the coefficients H1, H2, and H3 in Expression 21 are determined to offset the terms of E1 and E2 included in Expressions 20a to 20c. The following Expressions 22a to 22c are examples that satisfy this condition.

### [Math 22]

H1=Z⁻¹ (Expression 22a)

H2=Z⁻¹(1−Z⁻¹) (Expression 22b)

H3=1−2Z⁻¹+Z⁻²+Z⁻¹ (Expression 22c)

Substituting Expressions 20a, 20b, 20c, 22a, 22b, and 22c into Expression 21 yields the following Expression 23.

### [Math 23]

Y=Z⁻³×X+(1−Z⁻¹)³×E3 (Expression 23)

In Expression 23, the term of the quantization noises E1 and E2 are offset. Furthermore, the term of the quantization noise E3 is a product of the quantization noise E3 and (1−Z⁻¹)³. This indicates that the quantization noise is reduced as a result of the third-order noise shaping.

Although the first integrator 1101, the second integrator 1111, and the third integrator 1121 are single integrators according to Embodiment 2, they may be multiple integrators. Here, the coefficients H1, H2, and H3 for the digital filter 1170 may be determined to offset the terms of the quantization noises E1 and E2. The coefficients vary according to the order of the integrator or the number of stages of the delta-sigma modulators, not limited by the values indicated by Expressions 22a and 22b.

As described in Embodiment 1, the D/A converters are categorized into two types of bipolar and unipolar D/A converters. These D/A converters can be separately used depending on a range of input values. When an analog input signal to be input to the input terminal 1131 takes both positive and negative values, the first D/A converter 1103, the second D/A converter 1113, and the third D/A converter 1123 are desirably bipolar.

In contrast, when the analog input signal takes positive or negative values including 0, the first D/A converter 1103 may be unipolar. However, the second D/A converter 1113 and the third D/A converter 1123 are desirably bipolar. The reason will be described below. The input signal to be input to the second delta-sigma modulator 1116 indicates a quantization error introduced by the first delta-sigma modulator 1106. The quantization error has both positive and negative values. Furthermore, the input signal to be input to the third delta-sigma modulator 1126 indicates a quantization error introduced by the second delta-sigma modulator 1116. The quantization error has both positive and negative values. Here, if the second D/A converter 1113 and the third D/A converter 1123 are unipolar and the second feedback signal F11 and the third feedback signal F12 have both positive and negative values, the difference in range between the input signal and the feedback signal increases. As a result, the negative feedback loops of the second delta-sigma modulator 1116 and the third delta-sigma modulator 1126 do not normally operate, and easily become overloaded. This causes a larger error when an analog input signal is converted into a digital signal. Thus, the second D/A converter 1113 and the third D/A converter 1123 are desirably bipolar as described above.

The fourth feedback signal F13 desirably has both positive and negative values. For example, assume a case where the first feedback signal F10 and the fourth feedback signal F13 have positive values or 0. Here, when the input signal indicates 0 or closer, the loop easily becomes overloaded, and the error in A/D conversion easily becomes larger. The fourth feedback signal F13 having both positive and negative values offsets the input signal. Thus, adjusting the offset value negates the need to use the input signal in a range where the error increases.

When the signal to be input to the input terminal 1131 does not involve an input range having a larger error, such as values closer to 0, the fourth feedback signal F13 may have positive or negative values. Here, the third D/A converter 1123 may function as both bipolar and unipolar D/A converters.

According to Embodiment 2, the A/D converter 1100 may be used as an incremental A/D converter.

### [2-3. Advantages and Others]

The A/D converter 1100 according to Embodiment 2 includes the third delta-sigma modulator 1126, and feed backs the fourth feedback signal F13 generated by the third delta-sigma modulator 1126 to the input terminal of the first integrator 1101 in the first delta-sigma modulator 1106. Accordingly, the A/D converter 1100 can produce the noise shaping effect higher than that by the A/D converter including the delta-sigma modulators at two stages according to Embodiment 1. Thus, the high-accuracy A/D converter 1100 can be provided.

Furthermore, the A/D converter 1100 according to Embodiment 2 can make a mismatch in transfer function between delta-sigma modulators and a digital filter less sensitive as the A/D converter 100 according to Embodiment 1.

The A/D converter 1100 according to Embodiment 2 operates to reduce the terms of the quantization errors E1 and E2 that remain by the mismatch, with the negative feedback structure in which a feedback signal is fed back from the delta-sigma modulator at the last stage to the delta-sigma modulator at the first stage as the A/D converter 100 according to Embodiment 1. In other words, the A/D converter 1100 according to Embodiment 2 feeds back the total variation in the device using the fourth feedback signal F13. Thus, the high-accuracy A/D converter 1100 can be provided. Furthermore, the A/D converter 100 can retain high linearity.

### Embodiment 3

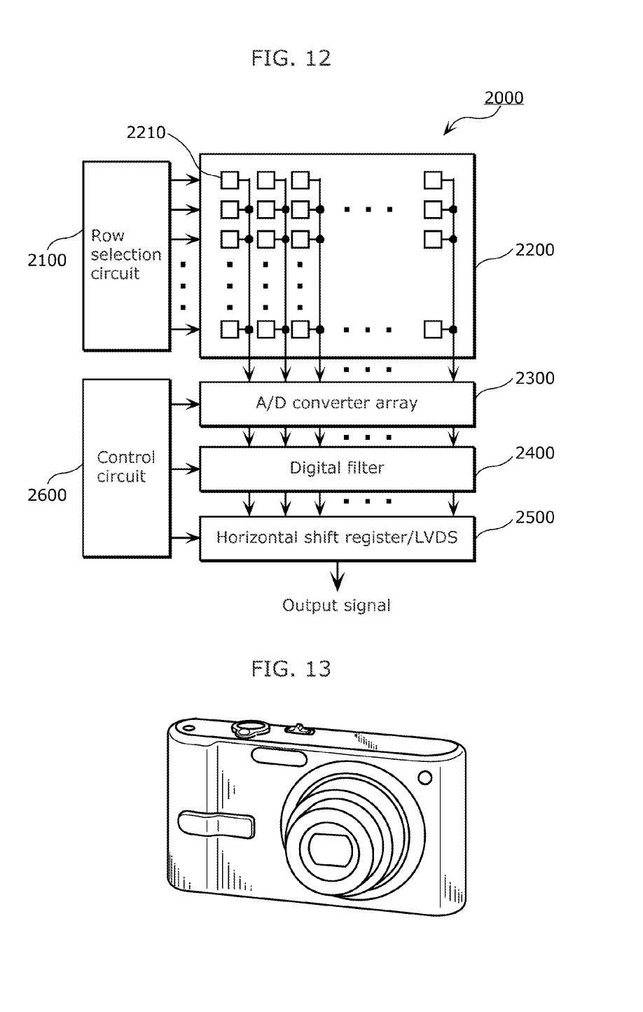

Embodiment 3 will be described with reference to FIGS. 12 to 14. Embodiment 3 will describe an image sensor (imaging device) and an imaging apparatus (digital still camera) that include the A/D converter according to each of Embodiments 1 and 2.

### [3-1. Structure]

FIG. 12 is a block diagram exemplifying a configuration of an image sensor 2000 according to Embodiment 3. The image sensor 2000 includes a pixel array 2200, a row selection circuit 2100, an A/D converter array 2300, a digital filter 2400, a horizontal shift register/low-voltage differential signaling (LVDS) 2500, and a control circuit 2600.

The pixel array 2200 is a matrix of pixels 2210. Specifically, the pixel array 2200 includes scanning lines, and signal lines crossing the scanning lines. The pixels 2210 are disposed at respective intersections between the scanning lines and the signal lines. The pixels 2210 in a row are connected to the same scanning line, and the pixels 2210 in a column are connected to the same signal line.

The row selection circuit 2100 sequentially selects (addresses) the scanning lines connected to the pixel columns that output pixel values.

The A/D converter array 2300 includes devices each including the A/D converter 100 (or 1100). The devices including the A/D converters 100 are disposed per column of the pixel array 2200. One of the devices including the A/D converters 100 may be shared among the pixel columns.

The digital filter 2400 includes a special effects filter, such as a polarizing filter or a color filter.

The horizontal shift register/LVDS 2500 is a register for outputting a signal output from the digital filter 2400, and applies the LVDS.

The control circuit 2600 controls operations of the A/D converter array 2300, the digital filter 2400, and the horizontal shift register/LVDS 2500.

### [3-2. Operations]

The operations of the image sensor 2000 will be hereinafter described. Upon receipt of an imaging request, the image sensor 2000 causes the row selection circuit 2100 to sequentially address the pixel rows included in the pixel array 2200. The pixels 2210 may be selected for each address vertically and horizontally, or in no particular order. The pixels 2210 disposed in the selected row output an analog signal having a voltage value corresponding to the quantity of charges stored in the signal line. This analog signal is input to each of the A/D converters in the A/D converter array 2300. Each of the A/D converters converts the analog signal (analog input signal) output from the pixels 2210 connected through the signal line, into a digital signal. The digital signals output from the A/D converter array 2300 are processed by the digital filter 2400. The digital signals processed by the digital filter 2400 are output from the image sensor 2000 through the horizontal shift register/LVDS 2500.

### [3-3. Variation of Embodiment 3]

The present disclosure may be implemented as a digital still camera including the image sensor 2000 as illustrated in FIG. 13. Furthermore, the present disclosure may be implemented as a digital video camera or a mobile phone. The digital still camera, the digital video camera, a camera module of the mobile phone, and others are examples of the imaging apparatuses. The image sensor 2000 is suitable as an imaging device in imaging apparatuses such as the digital still camera in FIG. 13 and camera modules for mobile devices including mobile phones.

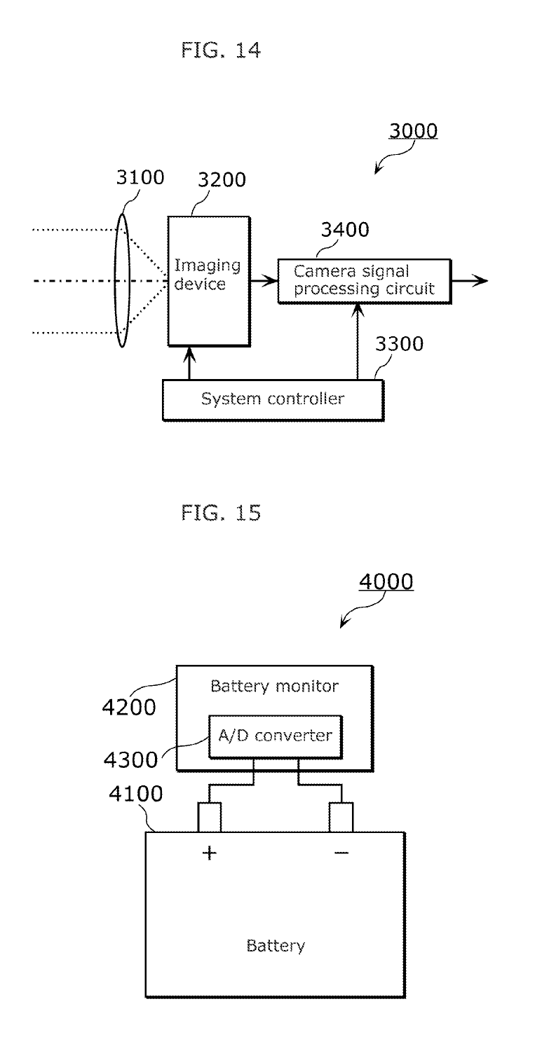

FIG. 14 is a block diagram of a configuration of a digital still camera including the image sensor according to Embodiment 3. As illustrated in FIG. 14, a digital camera 3000 according to Embodiment 3 includes an optical system including a lens 3100, an imaging device 3200, a camera signal processing circuit 3400, and a system controller 3300.

The lens 3100 forms an image light from an object, on an imaging area of the imaging device 3200. The imaging device 3200 converts the image light formed on the imaging area through the lens 3100 into an electrical signal per pixel to generate an image signal. The image sensor 2000 is used as the imaging device 3200. The camera signal processing circuit 3400 performs various signal processes on the image signal generated by the imaging device 3200. The system controller 3300 controls the imaging device 3200 and the camera signal processing circuit 3400.

### [3-4. Advantages and Others]

As described above, the image sensor 2000 includes A/D converters 100, the pixel array 2200 that is a matrix of the pixels 2210 each of which converts an optical signal into an electrical signal, and the digital filter 2400 that processes the digital signal output from each of the A/D converters 100 according to Embodiment 3.

Accordingly, the image sensor 2000 suppresses the error when the analog signal output from each of the pixels 2210 is converted into a digital signal. Thus, the image sensor 2000 according to Embodiment 3 can obtain high-accuracy image signals. Furthermore, the digital camera 3000 including the image sensor 2000 can capture high-accuracy images.

### Embodiment 4

Furthermore, the present disclosure may be implemented as an A/D converter in a battery monitoring system.

FIG. 15 is a block diagram exemplifying a configuration of a battery monitoring system 4000 according to Embodiment 4. The battery monitoring system 4000 includes a battery 4100 to be monitored, a battery monitor 4200, and an A/D converter 4300. The A/D converter 100 according to Embodiment 1 or the A/D converter 1100 according to Embodiment 2 is used as the A/D converter 4300.

The operations of the battery monitoring system 4000 will be hereinafter described.

The battery monitoring system 4000 is a system that monitors a voltage value of a battery. The battery monitor 4200 detects a voltage value of a battery, and outputs an analog signal indicating the voltage value of the battery. The A/D converter 4300 in the battery monitor 4200 converts the analog signal (analog input signal) into a digital signal.

As illustrated in FIG. 15, the battery monitoring system 4000 includes the A/D converter 100 according to Embodiment 1 or the A/D converter 1100 according to Embodiment 2. Accordingly, the battery monitoring system 4000 suppresses the error when the voltage value of the battery is converted into a digital signal. Thus, the voltage value of the battery can be monitored with higher accuracy.

### Other Embodiments

Although the A/D converters according to Embodiments 1 to 4, a method for driving the A/D converter, and a device including the A/D converter are described, the present disclosure is not limited to these Embodiments.

(1) Although the A/D converter according to each of Embodiments 1 to 4 includes the delta-sigma modulators at two or three stages, it may include delta-sigma modulators at four or more stages.

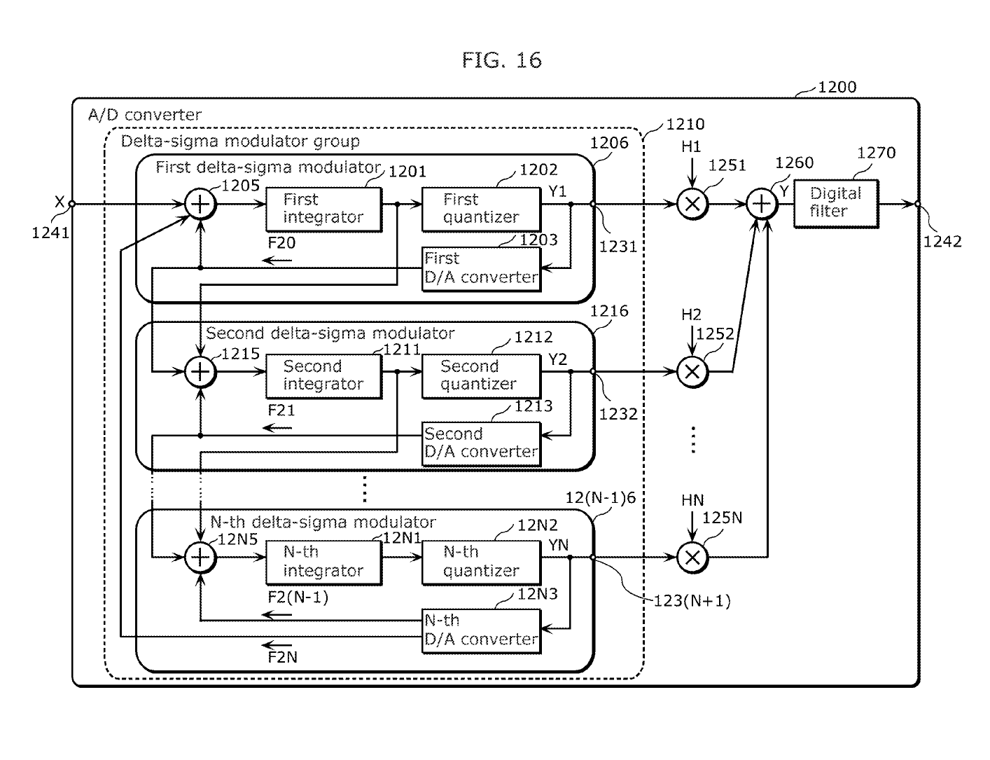

FIG. 16 is a block diagram of an A/D converter 1200 with N stages. As illustrated in FIG. 16, the A/D converter 1200 includes an input terminal 1241, a delta-sigma modulator group 1210, multipliers 1251 to 125N, an adder 1260, a digital filter 1270, and an external output terminal 1242.

The delta-sigma modulator group 1210 includes delta-sigma modulators at the N stages.

The configuration of a first delta-sigma modulator 1206 is the same as that of the first delta-sigma modulator 1106 according to Embodiment 2. The first delta-sigma modulator 1206 includes an adder 1205, a first integrator 1201, a first quantizer 1202, a first D/A converter 1203, and a first output terminal 1231 similarly as the first delta-sigma modulator 1106.

The configuration of each of a second delta-sigma modulator 1216 to an N-th delta-sigma modulator 12(N−2)6 is basically the same as that of the second delta-sigma modulator 1116 according to Embodiment 2. The second delta-sigma modulator 1216 includes an adder 1215, a second integrator 1211, a second quantizer 1212, a second D/A converter 1213, and a second output terminal 1232 similarly as the second delta-sigma modulator 1116.

The configuration of the N-th delta-sigma modulator 12(N−2)6 is basically the same as the third delta-sigma modulator 1126 according to Embodiment 2. In FIG. 16, F20 denotes a first feedback signal, F21 denotes a second feedback signal, F2(N−1) denotes a N-th feedback signal, and F2N denotes a (N+1)-th feedback signal. The A/D converter 1200 with the N stages can satisfactorily cancel the quantization error remaining by the mismatch in transfer function between the delta-sigma modulators and the digital filter, and accurately perform A/D conversion as the A/D converter 100 according to Embodiment 1 and the A/D converter 1100 according to Embodiment 2.

(2) Moreover, processing units included in the A/D converter and the image sensor according to Embodiments are typically realized as system LSIs which are integrated circuits. They may be made as separate individual chips, or as a single chip to include a part or all thereof.

Furthermore, the means for circuit integration is not limited to an LSI, and may be implemented by a dedicated circuit or a general-purpose processor. It is also acceptable to use a field-programmable gate array (FPGA) that is programmable after the LSI has been manufactured, and a reconfigurable processor in which connections and settings of circuit cells within the LSI are reconfigurable.

Embodiments have been described to exemplify the techniques of the present disclosure. Thus, the attached drawings and the detailed description are provided.

The constituent elements described in the attached drawings and the detailed description may include both essential ones for solving the problems and ones for exemplifying the techniques that are not essential for solving the problems. Thus, the attached drawings and the detailed description may include non-essential constituent elements.

Furthermore, since the embodiments herein exemplify the techniques of the present disclosure, various changes, replacement, addition, and omission may be performed within the scope of the claims or the equivalents.

Furthermore, division of the functional blocks in the block diagrams is one example. The functional blocks may be implemented as one functional block, one functional block may be divided into functional blocks, and a part of a function may be transferred to another functional block. Moreover, similar functions of functional blocks may be processed by single hardware or software in parallel or in a time division manner.

Furthermore, the circuit configuration in the circuit diagrams are examples, and the present disclosure is not limited to such a circuit configuration. In other words, the present disclosure involves a circuit which can implement characteristic features of the present disclosure as the circuit configuration. For example, the present disclosure involves an element to which an element such as a switching element (transistor), a resistor, or a capacitor is connected in series or in parallel, within a scope in which the same functions as those in the above circuit configuration can be implemented. In other words, “connected” in Embodiments 1 to 4 is not limited to the case where two terminals (nodes) are directly connected, but includes the case where the two terminals (nodes) are connected via an element, within the scope in which the same functions can be implemented.

Furthermore, the present disclosure involves various modifications to Embodiments 1 to 4 that are conceived by the person skilled in the art and other embodiments obtainable by combining the structural elements in different embodiments, without materially departing from the scope of the present disclosure.

Although only some exemplary embodiments of the present invention have been described in detail above, those skilled in the art will readily appreciate that many modifications are possible in the exemplary embodiments without materially departing from the novel teachings and advantages of the present invention. Accordingly, all such modifications are intended to be included within the scope of the present invention.

### INDUSTRIAL APPLICABILITY

The present disclosure is implemented as an element-variation-tolerable A/D converter, a driving method of the A/D converters, an image sensor and a battery monitoring system including the A/D converters.

1. An A/D converter, comprising:
a first integrator that integrates a signal obtained by adding a first feedback signal and a third feedback signal to an analog input signal, to generate a first output signal;
a first quantizer that converts the first output signal into a first digital signal;
a first D/A converter that converts the first digital signal into a first analog signal;
a second integrator that integrates a signal obtained by adding the first analog signal and a second feedback signal to the first output signal, to generate a second output signal;
a second quantizer that converts the second output signal into a second digital signal; and
a second D/A converter that converts the second digital signal into a second analog signal,
wherein the first feedback signal is the first analog signal,
the second feedback signal is the second analog signal, and
the third feedback signal is the second analog signal.

2. The A/D converter according to claim 1,
wherein the second D/A converter includes a bipolar D/A converter circuit.

3. The A/D converter according to claim 1,
wherein the second D/A converter includes a bipolar D/A converter circuit and a unipolar D/A converter circuit.

4. The A/D converter according to claim 1,
wherein the analog input signal has a level constantly higher than or equal to 0 or constantly lower than or equal to 0.

5. The A/D converter according to claim 1,
wherein the A/D converter is an incremental A/D converter.

6. An A/D converter, comprising:
a first integrator that integrates a signal obtained by adding a first feedback signal and a fourth feedback signal to an analog input signal, to generate a first output signal;
a first quantizer that converts the first output signal into a first digital signal;
a first D/A converter that converts the first digital signal into a first analog signal;
a second integrator that integrates a signal obtained by adding the first analog signal and a second feedback signal to the first output signal, to generate a second output signal;
a second quantizer that converts the second output signal into a second digital signal;
a second D/A converter that converts the second digital signal into a second analog signal;
a third integrator that integrates a signal obtained by adding the second analog signal and a third feedback signal to the second output signal, to generate a third output signal;
a third quantizer that converts the third output signal into a third digital signal; and
a third D/A converter that converts the third digital signal into a third analog signal,
wherein the first feedback signal is the first analog signal,
the second feedback signal is the second analog signal,
the third feedback signal is the second analog signal, and
the fourth feedback signal is the third analog signal.

7. The A/D converter according to claim 6,
wherein each of the second D/A converter and the third D/A converter includes a bipolar D/A converter circuit.

8. The A/D converter according to claim 6,
wherein at least one of the second D/A converter and the third D/A converter includes a bipolar D/A converter circuit and a unipolar D/A converter circuit.

9. The A/D converter according to claim 6,
wherein the analog input signal has a level constantly higher than or equal to 0 or constantly lower than or equal to 0.

10. The A/D converter according to claim 6,
wherein the A/D converter is an incremental A/D converter.

11. An A/D converter comprising delta-sigma modulators at a plurality of stages,
each of the delta-sigma modulators including: an integrator that integrates a signal obtained by adding a plurality of input signals and a feedback signal, to generate an output signal; a quantizer that quantizes the output signal into a digital signal; and a D/A converter that converts the digital signal into the feedback signal that is an analog signal,
wherein among the delta-sigma modulators, a delta-sigma modulator at a last one of the stages outputs the feedback signal to a delta-sigma modulator at a first one of the stages,
the input signals of the delta-sigma modulator at the first one of the stages include an analog input signal and the feedback signal from the delta-sigma modulator at the last one of the stages, and
the input signals of delta-sigma modulators at second and subsequent ones of the stages include a signal output from the integrator of each of delta-sigma modulators that precede the delta-sigma modulators at the second and subsequent ones of the stages, and the feedback signal from each of the delta-sigma modulators that precede the delta-sigma modulators at the second and subsequent ones of the stages.

12. An image sensor, comprising:
a pixel array that is a matrix of elements each of which converts an optical signal into an electrical signal that is an analog signal;
the A/D converter according to claim 1 that converts the analog signal output from the pixel array into a digital signal; and
a digital filter that processes the digital signal output from the A/D converter.

13. An image sensor, comprising:
a pixel array that is a matrix of elements each of which converts an optical signal into an electrical signal that is an analog signal;
the A/D converter according to claim 6 that converts the analog signal output from the pixel array into a digital signal; and
a digital filter that processes the digital signal output from the A/D converter.

14. An imaging apparatus comprising the image sensor according to claim 12.

15. An imaging apparatus comprising the image sensor according to claim 13.

16. A battery monitoring system comprising the A/D converter according to claim 1.

17. A battery monitoring system comprising the A/D converter according to claim 6.

18. A method for driving an A/D converter, the method comprising:
integrating a signal obtained by adding a first feedback signal and a third feedback signal to an analog input signal, to generate a first output signal;
converting the first output signal into a first digital signal;
converting the first digital signal into a first analog signal;
integrating a signal obtained by adding the first analog signal and a second feedback signal to the first output signal, to generate a second output signal;
converting the second output signal into a second digital signal; and
converting the second digital signal into a second analog signal,
wherein the first feedback signal is the first analog signal,
the second feedback signal is the second analog signal, and
the third feedback signal is the second analog signal.

19. A method for driving an A/D converter, the method comprising:
integrating a signal obtained by adding a first feedback signal and a fourth feedback signal to an analog input signal, to generate a first output signal;
converting the first output signal into a first digital signal;
converting the first digital signal into a first analog signal;
integrating a signal obtained by adding the first analog signal and a second feedback signal to the first output signal, to generate a second output signal;
converting the second output signal into a second digital signal;
converting the second digital signal into a second analog signal;
integrating a signal obtained by adding the second analog signal and a third feedback signal to the second output signal, to generate a third output signal;
converting the third output signal into a third digital signal; and
converting the third digital signal into a third analog signal,
wherein the first feedback signal is the first analog signal,
the second feedback signal is the second analog signal,
the third feedback signal is the second analog signal, and
the fourth feedback signal is the third analog signal.
